(19) United States
(12) Patent Application Publication
(10) Pub. No.: US 2022/0255194 A1
(43) Pub. Date: Aug. 11, 2022

(54) ELECTRONICS ASSEMBLY

(71) Applicant: RELECTRIFY HOLDINGS PTY, Victoria (AU)

(72) Inventors: Daniel Christopher CROWLEY, Victoria (AU); Babak Shoeiby, Victoria (AU); Jose Ralino Elias Gomes Prazeres, Victoria (AU); David Elias Jahshan, Victoria (AU); Miles Caples, Victoria (AU)

(21) Appl. No.: 17/659,159

(22) Filed: Apr. 13, 2022

Related U.S. Application Data
(63) Continuation-in-part of application No. PCT/AU2020/051112, filed on Oct. 16, 2020.

(30) Foreign Application Priority Data
Oct. 16, 2019 (AU) 2019903898

(51) Int. Cl. H01M 50/519; H01M 50/528; H05K 1/18; H01M 50/507

(52) U.S. Cl. CPC H01M 50/519; H01M 50/528; H01L 2924/351; H01M 50/507; H05K 1/189

(57) ABSTRACT

This application relates to electronics boards to span between cell terminals of multiple energy storage units. In various aspects, the electronics boards include at least one terminal coupling region configured as a primary path of electrical current between the electronics board and the cell unit terminals, at least one circuit region comprising at least a first conductive layer and a second non-conductive layer, and two or more electronic components disposed on the one or more electronics boards and connecting to the conductive layer in the circuit region. The terminal coupling regions and/or at least one part of the circuit regions have a defined mechanical bending characteristic and/or a combined thickness characteristic so as to permit at least some displacement from the predetermined geometrical alignment.

### CROSS-REFERENCE TO RELATED APPLICATIONS

This application is a continuation-in-part of PCT Application No. PCT/AU2020/051112, filed Oct. 16, 2020, which claims priority to AU Application No. 2019903898, filed on Oct. 16, 2019, the entire contents of each of which are incorporated herein by reference.

### INTRODUCTION

### Technical Field

The invention generally relates to electronics assemblies associated with energy storage systems, and in particular relates to a device and assemblies incorporating that device which facilitate mechanical or thermal stress relief between energy storage units.

### BACKGROUND

Energy storage systems for applications such as full electric vehicles, hybrid electric vehicles, and stationary energy storage in grid connected or off grid applications, frequently include an arrangement of multiple energy storage cell units.

In energy storage systems that include multiple energy storage cell units, the multiple cell units are usually connected to one another using conductive connectors such as busbars, metal tabs or metal strips. These conductive connectors are typically constructed from copper or aluminum. In addition, energy storage systems with multiple cell units frequently have separate control connectors to each cell unit terminal for the purpose of battery control, such as to measure the voltage of cell units and conduct currents to or from specific cell units to balance cell units. These control connectors often comprise flexible wires, which may have a conductive core and a non-conductive electrical insulation. Together, this usual approach has the advantages of high conductivity between the battery cells via conductive connectors, and by having separate conductive connectors between each set of cell units alongside flexible wires, is able to achieve a good electrical connection to battery cells with low resistance and high vibrational tolerance. However, this busbars and strips have the disadvantages of assemblies needing additional electronics boards, for example for the measurement and balancing electronics that connect to the flexible wires, having a large number of wires, which add cost, assembly complexity and breakage risk.

A less common approach is to interconnect energy storage systems by using electronics boards. These electronics boards often combine both conductive and non-conductive layers, are rigid in structure, and can provide both the electrical connections between the cell units, and the electrical connections for measurement and control of each cell unit. An electronics board that is a single physical component can provide electrical connection between multiple cell units, measurement and balancing, which reduces complexity and facilitates speed and simplicity assembly. Further, a single electronics board is able to integrate electronics components required for example for measurement or balancing. However, this less common approach has the disadvantages that a single board connecting to multiple connection points can potentially cause mechanical stress in the board and poor electrical connection if connection points of at least the multiple cell units are not perfectly aligned in a single plane. Further, due to cell units typically being heavy, when the units are subject to vibration, as may be common in their intended application, the movement of those units transfers mechanical stress into the electronics board which can lead to failures of the board or components on the board.

Another disadvantage of a single electronics board is that during notable heating and cooling, batteries and boards can experience different thermal expansion, which can also cause mechanical stresses in the boards. Furthermore, to provide high current capability, these board may have two or more layers of conductive material separated by other layers including one or more non-conductive layers, with electronic vias to electrically connect the two conductive layers. However, the distance between conductive layers, for example due to non-conductive layers, limits thermal conductivity between the conductive layers both near the vias and in sections without vias, which in turn may limit the thermal dissipation, and therefore the performance such as current capability, of such boards and electronic components mounted on them.

It is therefore an object of the invention to alleviate or improve upon the aforementioned disadvantages of the prior art, or at least provide the public with a useful choice. Other objects will be apparent to those skilled in the art.

### SUMMARY

According to some broad embodiments the invention relates to an electronic assembly comprising one or more electronics boards adapted to span between terminals of three or more energy storage units, the conductive terminals arranged in a predetermined geometrical alignment and configured as a primary path of electrical current to or from the energy storage units, the one or more electronics boards comprising at least one terminal coupling region configured as a primary path of electrical current between the electronics board and the unit terminals, and at least one circuit region comprising at least a first conductive layer and a second non-conductive layer; and wherein at least one part of the terminal coupling regions and/or at least one part of the circuit regions is characterized by: a mechanical bending characteristic so as to permit at least some displacement from the predetermined geometrical alignment and/or a combined thickness characteristic.

According to some broad embodiments the invention relates to electronic assembly comprising: one or more electronics boards adapted to span between terminals of three or more energy storage units, the cell unit terminals arranged in a predetermined geometrical alignment and configured as a primary path of electrical current to or from the energy storage units, the one or more electronics boards comprising: at least one terminal coupling region configured as a primary path of electrical current between the electronics board and the cell unit terminals, at least one circuit region comprising at least a first conductive layer and a second non-conductive layer, and two or more electronic components disposed on the one or more electronics boards and connecting to the conductive layer in the circuit region; and wherein at least one part of the terminal coupling regions and/or at least one part of the circuit regions is characterized by: a mechanical bending characteristic and/or a combined thickness characteristic so as to permit at least some displacement from the predetermined geometrical alignment.

In some embodiments, the circuit region comprises a primary current path between at least two terminal coupling regions, and wherein at least one of the electronic components is a switch component disposed in the primary current path and configured to selectively bypass and reversibly disconnect any one or more storage units from the series connection.

In some embodiments, the at least one of the terminal coupling regions is electrically coupled to one or more junctions between two serially connected energy storage units.

In some embodiments, the at least one of the plurality of energy storage units comprises a charge capacity of at least 20 ampere hours.

In some embodiments, the at least one of the electronic components comprises an electronics circuit board with mounted discrete components or an integrated electronic circuit element.

In some embodiments, the at least one of the terminal coupling regions and/or at least one of the circuit regions further comprises layers of a resiliently deformable material.

In some embodiments, the at least one of the terminal coupling regions and/or at least one of the circuit regions further comprises at least two conductive layers separated by at least one non-conductive layer, and one or more vias extending between the at least two conductive layers.

In some embodiments, the at least one of the circuit regions further comprises a layer substantially continuous with at least one of the terminal coupling regions.

In some embodiments, the at least one of the circuit regions further comprises one or more support layers, thereby altering the mechanical bending characteristic and/or the combined thickness characteristic in the circuit region proximate the one or more support layers.

In some embodiments, the one or more support layers are substantially continuous with at least one of the circuit regions and/or the terminal coupling regions of the electronics board.

In some embodiments, at least one of the plurality of energy storage units comprises a charge capacity of at least 20 ampere hours.

In some embodiments, at least one of the terminal coupling regions and/or at least one of the circuit regions further comprises layers of a resiliently deformable material.

In some embodiments, at least one of the terminal coupling regions and/or at least one of the circuit regions further comprises at least two conductive layers separated by at least one non-conductive layer, and one or more vias extending between the at least two conductive layers.

In some embodiments, at least one of the circuit regions further comprises a layer substantially continuous with at least one of the terminal coupling regions.

In some embodiments, at least one of the circuit regions further comprises one or more support layers, thereby altering the mechanical bending characteristic and/or the combined thickness characteristic in the circuit region proximate the one or more support layers.

In some embodiments, the one or more support layers are substantially continuous with at least one of the circuit regions and/or the terminal coupling regions of the electronics board.

In some embodiments, at least one of the circuit regions comprises: a primary current path between terminal coupling regions of at least two energy storage units, and one or more switch components disposed in the primary current path operable to selectively bypass and reversibly disconnect one or more energy storage units.

In some embodiments, the terminals comprise a terminal electrically coupled to a junction between two energy storage units.

In some embodiments, the circuit region comprises: one or more switch components connected to junctions between serially connected storage units, the switch components configured to selectively bypass and reversibly disconnect any one or more storage units from the series connection.

In some embodiments, the terminal coupling region is arranged for rigid coupling to the terminal of a storage unit by a fastener, fusing or welding.

In some embodiments, the terminal coupling region further comprises a temperature sensor configured to measure temperature of the assembly proximate the terminal.

In some embodiments, the terminal coupling region further comprises a voltage sensor configured to measure voltage at the terminal.

In some embodiments, the terminal coupling region further comprises a plurality of conductive segments, at least one segment is configured to couple to the temperature sensor and/or voltage sensor, and the primary current path comprises one or more other segments.

In some embodiments, the support layers comprise one or more slits, ridges, apertures and/or recesses disposed between at least some of the plurality of conductive segments of the terminal coupling region.

In some embodiments, one or more layers comprise one or more slits, ridges, apertures and/or recesses arranged to border, at least in part, the terminal coupling region.

In some embodiments, the terminal region comprises a conductive pad segmented by a plurality of non-conductive regions, at least some of the non-conductive regions comprising one or more slits, ridges, apertures and/or recesses.

In some embodiments, the primary current path further comprises one or more fuseable circuits arranged to couple at least one of the terminal coupling regions to at least one of the circuit regions and/or other terminal coupling regions.

In some embodiments, the one or more fuseable circuits comprise a printed conductive track having a geometrical constraint nominally configured for destruction above about 1000 amps.

In some embodiments, the electronics board comprises polyimide or KAPTON®.

In some embodiments, the electronic assembly further comprises a plurality of energy storage units, each having conductive terminals configured as a primary path of electrical current to or from the unit.

In some embodiments, the electronics assembly further comprises one or more captive fastener arrangements that maintain a bolt in position when not in a fastened state in relation to the electronics assembly and/or one or more energy storage units

In some embodiments, the bending characteristic is defined as one or more of: a) the electronic assembly having at room temperature a flexural modulus of less than 12 GPa; b) the electronic assembly having at room temperature a flexural modulus of around 6 GPa; c) the material in one or more non-conductive layers having at room temperature a flexural modulus of less than 10 GPa; d) the material in one or more non-conductive layers having at room temperature a flexural modulus of around 3 GPa; e) the electronic assembly having at room temperature a flexural strength of less than 300 MPa; f) the electronic assembly having at room temperature a flexural strength of around 150 MPa; g) the material in one or more non-conductive layers having at room temperature a flexural strength of less than 300 MPa; or the material in one or more non-conductive layers having at room temperature a flexural strength of less than 150 MPa.

In some embodiments, the combined thickness characteristic is defined by one or more of: a) one or more support layers having a thickness of around 1 mm; i) one or more support layers of more than 0.4 mm; b) one or more thin non-conductive layers and one or more conductive layers having a combined thickness of up to 0.4 mm; c) one or more thin non-conductive layers and one or more conductive layers having a combined thickness of up to 0.2 mm; d) one or more thin non-conductive layers and one or more conductive layers having a combined thickness of around 0.1 mm; e) a first non-conductive layer having a thickness of up to 0.08 mm; and/or f) a first non-conductive layer having a thickness of up to 0.02 mm.

In some embodiments, at least one of the terminal coupling regions and/or at least one of the circuit regions further comprise: a region where at least two conductive layers separated, at least in part, by at least one non-conductive layer, and a region where the two conductive layers comprises at least two conductive layers converging to directly contact one another.

In some embodiments, two or more non-conductive layers converge together in a region proximate to a switch component.

In some embodiments, at least one of the terminal coupling regions and/or at least one of the circuit regions further comprises: at least two conductive layers separated by at least one non-conductive layer; and one or more vias extending between the at least two conductive layers.

In some embodiments, the assembly further comprises a busbar configured to connect to at least one region of the circuit region and/or terminal coupling region.

In some embodiments, the circuit region comprises at least two conductive layers are separated, at least in part, by a non-conductive layer, and at least one of the electronic components is disposed on the conductive layer and between the at least two conductive layers of the circuit region.

In some embodiments, there is at least one spacer disposed in or through a non-conductive layer.

In some embodiments, the electronic assembly further comprises a component configured to apply a compression force through two or more layers.

In some embodiments, the assembly comprises at least one non-conductive layer provided to the assembly in a pre-compressed state.

In some embodiments, the invention relates to any one or more of the above statements in combination with any one or more of any of the other statements. Other aspects of the invention may become apparent from the following description which is given by way of example only and with reference to the accompanying drawings.

The entire disclosures of all applications, patents and publications, cited above and below, if any, are hereby incorporated by reference. This invention may also be said broadly to consist in the parts, elements and features referred to or indicated in the specification of the application, individually or collectively, and any or all combinations of any two or more of said parts, elements or features, and where specific integers are mentioned herein which have known equivalents in the art to which this invention relates, such known equivalents are deemed to be incorporated herein as if individually set forth.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

The term “and/or” referred to in the specification and claim means “and” or “or”, or both. The term “comprising” as used in this specification and claims means “consisting at least in part of”. When interpreting statements in this specification and claims which include that term, the features, prefaced by that term in each statement all need to be present but other features can also be present. Related terms such as “comprise” and “comprised” are to be interpreted in the same manner.

As used herein, the singular forms “a,” “an,” and “the” are intended to include the plural forms as well, unless expressly stated otherwise. It will be further understood that the terms “includes,” “comprises,” “including,” and/or “comprising,” when used in this specification, specify the presence of stated features, integers, steps, operations, elements, and/or components, but do not preclude the presence or addition of one or more other features, integers, steps, operations, elements, components, and/or groups thereof. It will be understood that when an element is referred to as being “connected” or “coupled” to another element, it can be directly connected or coupled to the other element or intervening elements may be present.

### DESCRIPTION OF THE DRAWINGS

The invention can be better understood with reference to the following drawings. The elements of the drawings are not necessarily to scale relative to each other, emphasis instead being placed upon clearly illustrating the principles of the invention. Furthermore, like reference numerals designate corresponding parts throughout the several views.

FIG. 1 shows an exemplary electronic assembly attached to eight battery modules.

FIG. 2A and FIG. 2B shows an exemplary electronic assembly attached to twenty-four battery modules.

FIG. 3 shows the electronic assembly of FIG. 1 in further detail.

FIG. 4 shows an example of an electronics assembly with switching components attached to three battery modules and arranged for the selective bypass of any one or more of those battery modules.

FIG. 5 shows a cross-section of the exemplary electronic assembly of FIGS. 1 and 3.

FIG. 6 shows a detailed sectional view of an exemplary embodiment of an electronic assembly with different layers.

FIG. 7 shows an exemplary embodiment of an electronic assembly which has conductive and non-conductive layers, and a heatsink element.

FIG. 8 shows an exemplary embodiment of an electronic assembly

FIG. 9A shows a top isometric view of the assembly of FIG. 8 and FIG. 9B shows a bottom view of the assembly.

FIG. 10 shows a bottom view of another exemplary electronics assembly.

FIG. 11 shows another exemplary embodiment of an electronics assembly.

FIG. 12 shows a close up view of an exemplary electronic assembly, and in particular, a terminal coupling region.

FIG. 13 shows an example electronics circuit for implementation on any of the described electronics assemblies.

FIG. 14 shows an example electronics circuit for implementation on any of the described electronics assemblies having a mechanical bending characteristic to permit displacement from a predetermined geometrical alignment and/or a combined thickness characteristic.

FIG. 15 shows a top view of an exemplary embodiment of an electronic assembly where a single electronics board is adapted to span between multiple cell unit terminals.

FIG. 16 shows an example of an electronic circuit for implementation on the any of the electronics assemblies.

FIG. 17 shows the bottom isometric view of an exemplary embodiment of the bottom of an electronics assembly.

FIG. 18 shows the bottom view of another exemplary embodiment of the electronic assembly with cut-outs at points of attachment to a cell unit.

FIG. 19 shows an exemplary embodiment of an electronic assembly an electronics board laminate of six layers, the board also supporting electronic components.

FIGS. 20A-20C show aspects of exemplary component packages of a semiconductor assembly.

FIGS. 21A-21E show aspects of exemplary component packages of a semiconductor assembly.

FIGS. 22A, 22B, and 22C show aspects of exemplary component packages of a semiconductor assembly.

FIGS. 23A and 23B show a pair of exemplary embedded switch components that are configured with connected drain and source terminals.

FIGS. 24A, 24B, and 24C show exemplary and representative embodiments where the electronic assembly further comprises additional vertically arranged layers.

FIGS. 25A, 25B, 25C, 25D and 25E show an exemplary embodiment of an electronic assembly where a single electronics board is adapted to span between two terminals of a single cell.

FIGS. 26A and 26B show aspects of electronics boards comprising terminal coupling regions arranged in a predetermined geometrical alignment and adapted for connection to terminals of energy storage units.

### DETAILED DESCRIPTION

Embodiments of the present disclosure are now described.

Exemplary methods, devices, assemblies and systems are described herein. It should be understood that the word “exemplary” is used herein to mean “serving as an example, instance, or illustration.” Any embodiment or feature described herein as “exemplary” or “illustrative” is not necessarily to be construed as preferred or advantageous over other embodiments or features. More generally, the embodiments described herein are not meant to be limiting. It will be readily understood that certain aspects of the disclosed systems and methods can be arranged and combined in a wide variety of different configurations, all of which are contemplated herein.

The invention includes one or more electronic boards and an assembly including electronics boards which span between terminals of multiple energy storage cell units. To address the aforementioned disadvantages the electronics boards integrate one or more features which facilitate a measure of flexibility, deformability or resilience so that mechanical stress, thermal stress or thermal energy which is generated in the boards themselves, generated in components attaching to the boards, and/or transferred to the boards from the cell units does not destructively affect the boards or components supported by the boards or at least such stress or heating is mitigated.

In this specification, the terms “battery cell unit” or “cell unit” are generally intended to refer to a component which can store an electrical charge and can refer to an individual battery cell or a block of cells connected in parallel, or a multitude of individual battery cells or blocks of parallel cells or a mix of cells connected in series. An energy storage unit may also refer to a block of cells connected in parallel and/or series and which further includes circuit components such as fuses, resistors, passively controlled diodes, capacitors or inductors are connected in series and/or parallel with individual cells. The term “energy storage unit”, “storage unit”, “battery cell unit” or “cell unit” may also refer to non-battery energy storage elements such as fuel cells and supercapacitors.

In some embodiments, the energy storage units may be designed to include one or more energy storage units enabling a charge capacity of at least 10 Ah, 20 Ah 40 Ah, 60 Ah, 100 Ah, 200 Ah, or 400 Ah ampere hours. In some embodiments, the plurality of energy storage units may comprise a first and a second energy storage unit, with the first energy storage unit having a charge capacity that is substantially larger than the charge capacity of the second energy storage unit.

In preferred embodiments, there are one or more electronics boards which are adapted to span between terminals of three or more energy storage units. In industrial applications, the terminals of the storage units will be arranged in a predetermined alignment to best suit packaging constraints of the application, due to variations in cell unit sizing or inconsistencies in cell unit alignment or for other reasons such as proximity to electrical loads or cooling sources. The predetermined geometrical alignment of conductive terminals are configured as a primary path of electrical current to or from the energy storage units.

The terminals will have a predetermined geometrical arrangement typically dictated by the requirements of their application or purpose. For example, to optimize the coupling of electrical current between units, the terminals of the units are often arranged to enable an electronics assembly in a single plane to contact all terminals. However, the terminals may be in an arrangement where at least one terminal is spatially offset compared to one or more other terminals. For example, there may be physical constraints due to one or more other parts of an energy storage module, racking, enclosures, or other nearby parts that may collide with the plane of the terminals which may then dictate a misalignment of the terminals.

The one or more electronics boards have a number of terminal coupling regions which are intended to be attached to the terminals of the storage units. The terminal coupling regions are configured as a primary path of electrical current between the electronics board and the unit terminals and used to charge or discharge the energy storage units as may be required.

In this specification, the term “primary path of electrical current” or similar refers to a relatively high current path between cell unit terminals. The term “secondary path of electrical current” or similar refers to a relatively low current path from cell terminals to secondary devices such as voltage monitoring devices, or charge balancing devices. A primary current path may include conductive parts of an electronic assembly such as terminal coupling regions and circuit regions. Further, the electronic assembly may have electronic components disposed in the primary current path and configured to disrupt the primary current path. For example, the primary current path may be disrupted by disconnecting a cell, or bypassing a cell. The primary path of electrical current is the electrical path which is predominantly used for charging and discharging when the current flows through all battery cell units. In some embodiments, the primary current path is selectively operated by selective operation of the electronic components.

The primary path of electrical current is objectively distinct from a secondary path of electrical current. A secondary current path is operable for tasks such as cell balance charge or cell balance discharge tasks, voltage sensing, bypassing batteries, probe measurements of batteries or similar relatively low current tasks. The secondary current path is often not physically capable of supporting maximum charge or discharge current of the cell unit.

Another way to distinguish a primary current path from a secondary current path is that in most battery arrangements, when all energy storage cell units are connected in series and no energy storage cell unit is partially or fully bypassed, then the current that flows runs through the primary current path and not the secondary current path.

Another way to distinguish a primary current path from a secondary current path is by consideration of the current a particular circuit path is configured to support. For example, a typical battery cell may have a 10 or more ampere charge or discharge current carrying ability when the primary path is used, and that cell may also have a 1 ampere or less current ability when a secondary path is used. Therefore, a primary current path is typically configured to support at least 10 times (or significantly higher current than) the current of a secondary current path.

The secondary current path is often physically distinct from the primary current path by virtue of the different current carrying requirements. As such, a primary current path is typically configured with a larger physical conductive surface area than a secondary current path.

Further, the electronics boards have at least one circuit region which is typically used to support components such as discrete components, sensors, or any other electrical device which may be usefully connected to. The circuit region has in some areas at least a first conductive layer and a second non-conductive layer so as to form a circuit path, and substrate for that circuit path.

The preferred implementation of the electronics boards are printed circuit boards. The circuit board is typically constructed from a laminate of layers. Any layer in the laminate may be a conductive layer or a nonconductive layer. In some embodiments, conductive layers may comprise aluminum or copper. In some embodiments, non-conductive layer materials include polyimide, KAPTON® tape, polyethylene terephthalate or polyethylene naphthalate. In some embodiments, one or more support layers may comprise of glass-reinforced epoxy laminate, e.g. FR4, or aluminum.

The conductive layers are typically metal such as copper or plated copper. Where two or more conductive layers separated by a nonconductive layer is used, vias may be used to electrically and thermally connect those layers. Heat is often generated from electronics components mounted on the electronics assembly, such as switches, diodes, fuses, or other components and that heat is able to be efficiently transferred by the arrangement conductive layers and vias.

To address the mechanical stresses, thermal stresses or thermal energy, a terminal coupling region and/or the circuit region is characterized by: a mechanical bending characteristic so as to permit at least some displacement from the predetermined geometrical alignment, or to allow connection to terminal which are not in a precise alignment and/or a combined thickness characteristic.

The mechanical bending characteristic is facilitated by a region of the circuit region or terminal region whereby that region is comparatively flexible so as to form a region of deformation and/or comparatively thin. This has one or more of the advantages as follows:

If connection points, e.g. multiple cell terminals, are not perfectly aligned, the electronics boards can bend without undue stress on the board.

During notable heating and cooling, if batteries and boards experience different thermal expansion, electronics boards can bend without undue stress on the board.

Atypically thin boards, e.g. with two conductive layers either side of a thin non-conductive layer, may have high thermal conductivity between the two conductive layers, both at vias and in areas without vias, and therefore enable high performance such as current capability in the boards and electronic components mounted on them.

### Bending Characteristics

In some exemplary embodiments, one or more of the electronics boards are characterized by a measure of bending of a part of the terminal coupling region or a circuit region according to the following: a bend of 10 degrees or more at a bend radius of up to 5 cm, a bend of 15 degrees or more at a bend radius of up to 5 cm, a bend of 30 degrees or more at a bend radius of up to 5 cm, or a bend of 45 degrees or more at a bend radius of up to 5 cm, such that the conductive layer is operable to allow current flow throughout and after such bending.

In some exemplary embodiments, one or more of the electronics boards are characterized by a measure a bending of a part of the terminal coupling region or of a part of the circuit region according to the following (at around 20 degrees Celsius): a flexural modulus of less than 12 GPa, a flexural modulus of around 6 GPa, a flexural strength of less than 300 MPa, or a flexural strength of around 150 MPa.

In some exemplary embodiments, one or more non-conductive layers are characterized by a flexural modulus of (at around 20 degrees Celsius): less than 10 GPa, a flexural modulus of around 3 GPa, a flexural strength of less than 300 MPa, or a flexural strength of around 150 MPa.

### Thickness Characteristics

In some embodiments, at least one of the terminal coupling regions and/or at least one of the circuit regions are characterized by a combined thickness characteristic. In other embodiments, at least one of the terminal coupling regions and/or at least one of the circuit regions are characterized by a thickness characteristic of at least a particular layer. The thickness characteristic is selected to optimize or improve a thermal energy transfer behavior.

In some embodiments having two or more conductive layers separated by one or more non-conductive layers, having comparatively thin non-conductive layers between to conductive layers may enable the conductive layers to more efficiently distribute thermal energy.

In some embodiments, the one or more electronics boards comprises at least a first non-conductive layer and at least a first conductive layer, and the electronics boards are characterized by a combined thickness of: less than 0.4 mm, less than 0.2 mm, or around 0.1 mm.

In some embodiments, the one or more electronics boards comprises at least a first non-conductive layer and at least a first conductive layer, and the electronics boards are characterized by a combined thickness of about 0.05 to 0.4, 0.1 to 0.4, 0.15 to 0.4, 0.2 to 0.4, 0.25 to 0.4, 0.3 to 0.4, 0.35 to 0.4, 0.05 to 0.35, 0.05 to 0.3, 0.05 to 0.25, 0.05 to 0.2, 0.05 to 0.15, or 0.05 to 0.1 mm.

In some embodiments, the one or more electronics boards comprises at least a first non-conductive layer and at least a first conductive layer, and the electronics boards are characterized by a combined thickness of about 0.05 to 0.2, 0.1 to 0.2, 0.15 to 0.2, 0.05 to 0.15, or 0.05 to 0.1 mm.

In some embodiments, an optimum value for one conductive layer flex is about 0.08 mm. Other values are possible, however performance may be reduced where departing values are implemented. In some embodiments, an optimum value for two conductive layer flex is about 0.1 mm. Other values are possible, however performance may be reduced where departing values are implemented.

In some embodiments, a range of thickness values for a board comprising two conductive layers is between about 0.05 mm to about 0.1 mm, noting that increasing the spacing between conductive layers lowers thermal transfer between layers, which may in turn lower the efficiency of heat dissipation. That is, heat dissipation performance may be improved as the non-conductive layer become thinner.

In some embodiments, a range of thickness values for a board comprising more than two conductive layers or thicker conductive layers is between about 0.05 mm to about 0.2 mm.

In some embodiments, a non-conductive layer has a practical minimum thickness of about 0.01 or 0.025 mm for a non-conductive layer material implementation. In some embodiments, a first non-conductive layer is characterized by a thickness of: up to 0.08 mm, or up to 0.02 mm. In some embodiments, an optimum thickness of a non-conductive layer of non-conductive material is either 0.0125 mm or 0.025 mm. In some embodiments, an optimum range of layer thicknesses is at least about 0.005 mm and 0.025 mm. In some embodiments, a non-conductive layer is between about 0.005 mm and 0.025 mm, 0.01 mm and 0.025 mm, 0.015 mm and 0.025 mm, 0.020 mm and 0.025 mm, 0.005 mm and 0.020 mm, 0.005 mm and 0.015 mm, or 0.005 mm and 0.010 mm.

Comparatively, a FR4 PCB material has a practical thickness of around 1 mm. While it is noted thin FR4 boards are able to be manufactured at thicknesses of 0.2 mm. In some embodiments, non-conductive layers comprise a FR4 or similar material layer of about 0.2, 0.3, 0.4, 0.5, 0.6, 0.7, 0.8, 0.9 or 1 mm. Further, in some embodiments, non-conductive layers comprise a FR4 or similar material layer of about 0.2 to 1.0, 0.3 to 1.0, 0.4 to 1.0, 0.5 to 1.0, 0.6 to 1.0, 0.7 to 1.0, 0.8 to 1.0 or 0.9 to 1.0. Further, in some embodiments, non-conductive layers comprise a FR4 or similar material layer of about 0.2 to 0.9, 0.2 to 0.8, 0.2 to 0.7, 0.2 to 0.6, 0.2 to 0.5, 0.2 to 0.4, or 0.2 to 0.3 mm.

In some embodiments, in addition non-conductive and conductive layers, there may also be additional adhesive layers interspersed between other layers. In some embodiments, there may also be additional prepreg layers or other reinforcing layers interspersed among other layers.

### Support Layers

In some embodiments, some regions of the electronics boards are supported by one or more discrete segments which facilitate further rigidity in the region of the segment aligned with and proximate to the point at which the segment is attached. Such segments are herein referred to as support layers. In effect, the support layers alter the mechanical bending characteristic and/or the combined thickness characteristic in the circuit region proximate the one or more support layers. In some embodiments, one or more support layers are characterized by a thickness of around 1 mm or of more than 0.4 mm. In some embodiments, the electronics boards are a laminate where some layers are arranged to span between multiple terminal coupling regions, and other layers are located on regions of the support board where increased rigidity is desired.

Additional rigidity provided by a support layer is beneficial in areas where the electronic assembly is connected to optional discrete electronics components or electronics elements, which are comparatively sensitive to mechanical stresses in the connected electronic assembly and where the additional mechanical rigidity may therefore protect from breakages or other issues.

In some embodiments, the support layer is conductive and is configured to carry current within the electronic assembly.

In some embodiments, the support layers comprise one or more slits, ridges, apertures and/or recesses. An optimum location of the support layers is where they are arranged to surround, at least in part, border and/or pass through the terminal coupling region. The particular arrangement is determined by the arrangement of interconnected cells and load paths the cell mass creates, combined with local regions of thermal expansion.

### Terminal Coupling Regions

The abovementioned terminal coupling regions are configured for coupling the electronics board to the terminal of a cell unit. The terminal coupling region may be attached by any conventional coupling method such as by a fastener, fusing or welding.

In some embodiments, the terminal coupling region is configured to connect to one or more sensors. For example, a voltage sensor or a temperature sensor. Due to resistive losses which occur in any conductor, it is advantageous to connect a voltage sensor or sensing couple to a separate measurement connection, rather than on connection for a primary current path. Similarly, it is advantageous for a temperature sensor to be located to measure temperature of the assembly proximate the terminal so that the temperature best represents the temperature of the assembly at the cell unit.

In some embodiments, the terminal coupling region is divided into a plurality of conductive segments. The segments are arranged such that some segments are configured as part of a primary current conduction path, and other segments are configured for connection to a temperature sensor and/or voltage sensor. By isolating segments of the terminal coupling region from others, the voltage sensor location has improved isolation from primary current path and any voltage offsets created on that path. Exemplary embodiments discussed below illustrate a segmented terminal coupling region and implementations.

### Gap Features

In some embodiments, support layers are defined by one or more cut out or recessed areas of the electronics boards as to facilitate relative displacement of the electronics boards regions either side of the cut out or recessed areas. In some varied embodiments, terminal coupling regions incorporate a form of cut out. Such a cut out can, in some embodiments, form the aforementioned segments of terminal coupling region.

In some embodiments, the support layers are defined by one or more of slits, ridges, apertures and/or recesses arranged to border, at least in part, the terminal coupling region.

In some embodiments, the terminal region has a conductive pad as an outermost layer segmented by a plurality of regions with a non-conductive outermost layer and where at least some of the regions comprise one or more slits, ridges, apertures and/or recesses.

### Other Features

In some embodiments, the primary current path formed by a conductive layer of the electronics boards has one or more fuseable circuits arranged to couple at least one of the terminal coupling regions to at least one of the circuit regions and/or other terminal coupling regions. The fuseable links are intended to prevent large current from being discharged from the cell units which may occur, for example, in the unlikely event of a component failure, or an accident event which causes damage to electrical components or current paths. The fuseable link is intended to remain intact during regular use, and fail when subject to current levels well above any operating level.

In some embodiments, at the location of the fuseable link, the conductive layer comprising the link is covered by a non-conductive layer located either side of the conductive layer. The non-conductive layers protect against any contaminants which could adversely influence the performance of the fuseable link. The non-conductive layers provide a level of protection of activated fuse components departing significantly from its site to a disadvantageous location.

In other embodiments, at the location of the fuseable link, the conductive layer comprising the link is covered only on one side by a non-conductive layer. In other embodiments, the fuseable link is uncovered on both sides.

In some embodiments, the terminal coupling region may define a conductive layer with a geometrically constrained circuit path designed to fail at: about 50 amperes or more, about 100 amperes or more, about 200 amperes or more, about 500 amperes or more, about 1000 amperes or more, about 2000 amperes or more, and/or about 5000 amperes or more.

In some embodiments, the energy storage units may be designed to achieve a maximum charge or discharge current to one or more energy storage units of at least 3 amperes, 10 amperes, 30 amperes, 50 amperes, 100 amperes, 400 amperes or a different current level.

In some embodiments, the electronic assembly supports electronic switching components that are selectively operated to enable connection or bypass of any one or more battery cell units from a series arrangement. The operation may further entail selective disconnection and reconnection, where disconnecting a battery cell from a series arrangement is performed in a reversible way such that the battery cell can thereafter be selectively reconnected to the series arrangement. Selective bypassing of cells from a series arrangement achieves different connection states and allows variation, for example, in the output voltage of the series arrangement. Operation of the electronic switching components is possible during charging and/or discharging of one or more battery cell units in the series arrangement.

Where there are three battery cell units, the connection states may include a first state in which the first battery cell unit and the second battery cell unit are electrically connected in series and the third battery cell unit is disconnected; a second state in which the first battery cell unit and the third battery cell unit are electrically connected in series and the second battery cell unit is disconnected; and a third state in which the second battery cell unit and the third battery cell unit are electrically connected in series and the first battery cell unit is disconnected.

Where there are four battery cell units, the states may include the above three states, as well as a fourth state in which the first battery cell unit, the second battery cell unit and the fourth battery cell unit are electrically connected in series and the third battery cell unit is disconnected; and a fifth state in which the first battery cell unit, the second battery cell unit, the third battery cell unit and the fourth battery cell unit are electrically connected in series.

By controlling the number of cell units connected in series, the electronic assembly may be able to control the resulting voltage at the outputs of one or a multitude of electronic assemblies.

In some embodiments, the electronic assembly supports electronics components that are operated in such a way that in addition to connecting or bypassing any of a number of battery cell units from a series arrangement, individual battery cell units or groups of battery cell units can additionally be inverted. In one control state, such an electronic assembly may have a first output terminal with a comparatively positive voltage potential in respect to a second output terminal. In a second control state, such an electronic assembly may have the first output terminal with a comparatively negatively voltage potential in respect to a second output terminal.

In some embodiments, the electronics components on the electronic assembly may be operated in such a way that multiple battery cell units are series-connected while one or more battery cell units are connected to a resistive element for the purpose of discharging these one or more battery cell units or reducing the charging of these one or more battery cell units. In another embodiment, the electronics components on the electronic assembly may be operated in such a way that multiple battery cell units are series-connected while one or more battery cell units are connected to an energy transfer element for the purpose of transferring energy from a first cell unit to one or more other cell units, or to transfer energy from one or more other cell units to the first cell unit. The energy transfer elements could for example include one or more of capacitors, inductors, transformers, DC/DC converters and/or batteries.

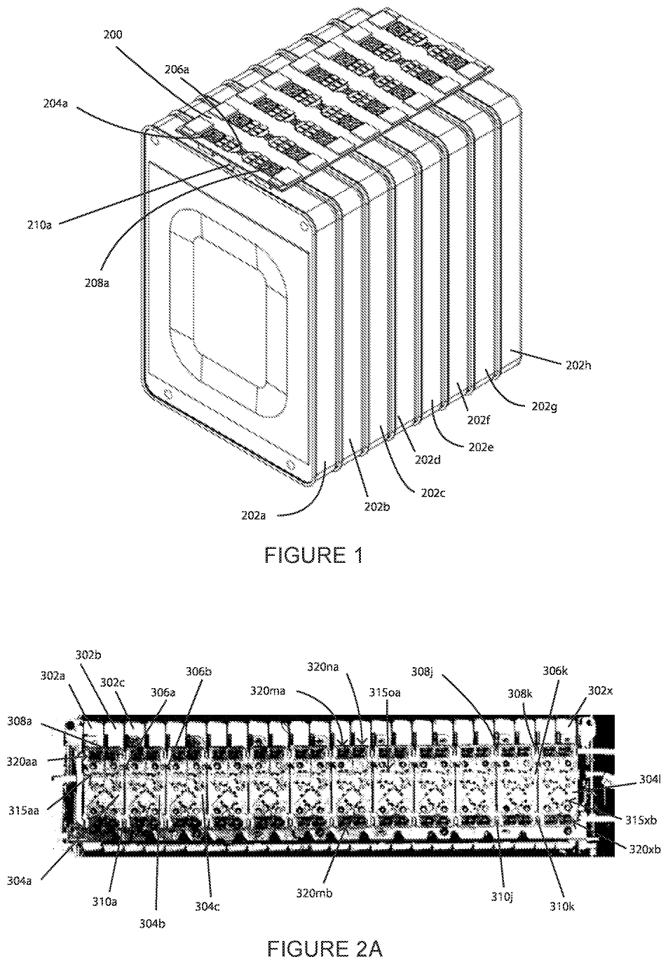

FIG. 1 shows an exemplary electronic assembly. In this example, the electronic assembly has one electronics board 200 designed to attach to eight battery modules 202a-202h. Each battery module in the depicted example has two battery cell units that are connected in series. However, many other combinations of cell units are possible. This means that the positive terminal of a first cell unit within a first module 202a, and the negative terminal of a second series-connected cell unit within module 202a are connected together at terminal 210a and connect to the electronic assembly at one contact point 206a. The negative terminal of the first cell connects to the electronic assembly at a separate contact point 204a. The positive terminal of the second cell also connects to the electronic assembly at a separate contact point 208a.

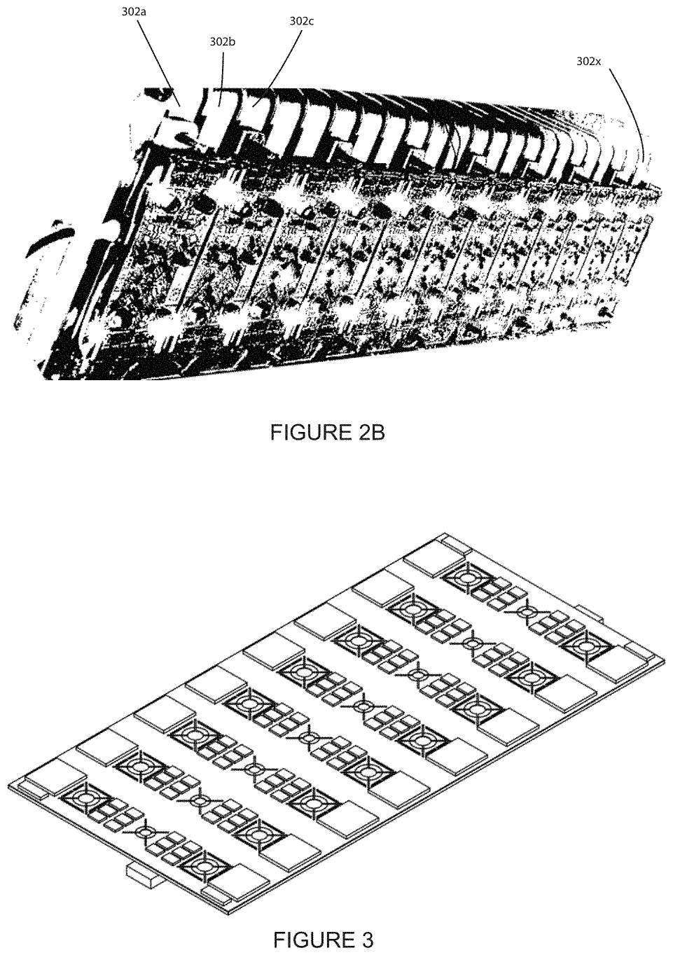

FIG. 2A and FIG. 2B shows an exemplary electronic assembly attached to twenty-four battery modules 302a-302x. In this example, the electronic assembly has twelve discrete electronics boards 304a-3041. Each board is configured to attach to two battery modules. It should be appreciated that any number of modules or boards or battery cells in each module could be implemented according to desired voltage, current or capacity requirements. Each battery module consists of two battery cell units that are connected in series. The electronics boards are connected to adjacent boards, including via electrical connectors 306a-306k that conduct the current that flows through one or more cell units. The electronics boards are also connected to one-another via control connectors 308a-308k and 310a-310k that enable sharing of encoded communications signals or physical control signals such as pulses, sine waves, or other time-varying unencoded signals.

Further, the electronics assembly includes electronic components 320aa-320xb that are electronics circuit boards with mounted discrete components. The electronics assembly also includes electronic components 315aa-315xb that are switch components disposed in the primary current path and configured to selectively bypass and reversibly disconnect any one or more battery cell units from a series connection of battery cell units.

FIG. 3 shows the electronic assembly of FIG. 1 in further detail. In this exemplary embodiment, the electronic assembly is a single one electronics board comprising of a repeated structure intended for connection and attachment to eight battery modules. Each battery module consists of two battery cell units that are connected in series. The largest component of the electronic assembly may be a printed circuit board implemented according to thickness and/or bending characteristics outlined above. The large raised squares along the outside are electronic circuit elements such as secondary electronics circuit boards with mounted components or other integrated electronic circuit elements such as FPGAs or ASICs.

The two sets of three little raised squares per module are optional electronics components. These electronics components could be switch components, such as transistors, IGBTs or MOSFETs that can be used to achieve connection states enabling a change of the batteries that are connected in series with one another. For example, of the sixteen battery cell units connecting the electronic assembly in this embodiment, at a specific point in time, the electronics components on the electronic assembly may be operated in such a way that ten specific cell units may be electrically connected in series, and the remaining six cell units may not be electrically connected in series with the ten cell units. At a different point in time, the electronics components on the electronic assembly may be operated in such a way that nine cell units, which may be a mix of the previous ten cell units and some of the previous six cell units, may be electrically connected in series, and the remaining seven cell units may not be electrically connected in series with the nine cell units. In fact, the electronics components on the electronic assembly may be configured in such a way that it can achieve different operating states that enable any chosen number and set of battery cell units to be connected in series, while any other battery cell units connected to the electronic assembly may not be electrically connected in series with the series-connected battery cell units.

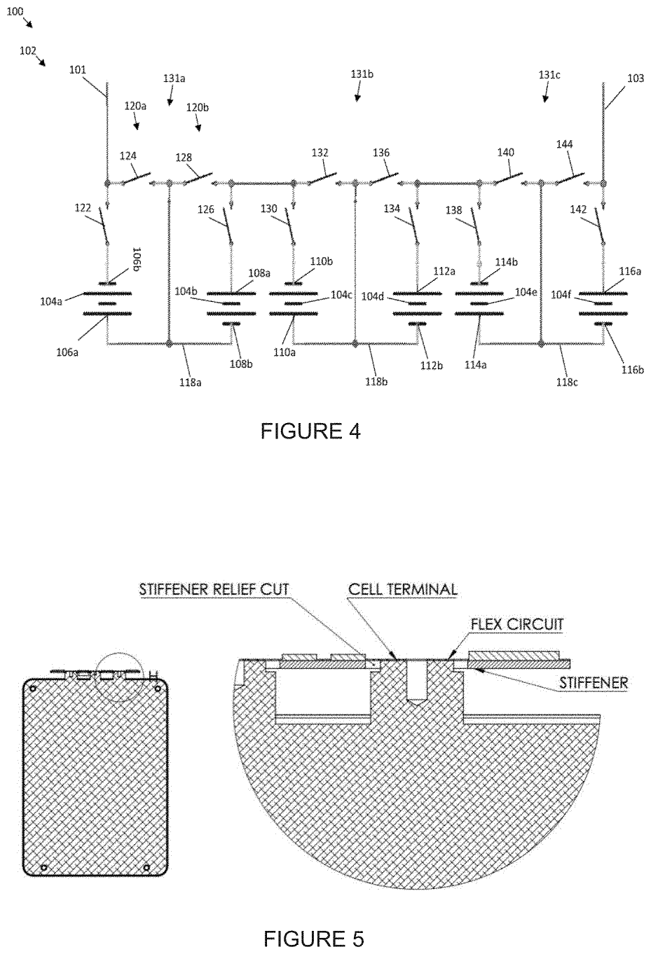

FIG. 4 shows an example of a battery system including an electronics assembly 100 with switching components (122-144) attached to three battery modules (104a-f) and arranged for the selective bypass of any one or more of those battery modules. Each battery module consists of two battery cell units that are connected in series. The electronics assembly has a predetermined geometrical alignment and/or a combined thickness characteristic, and the switching components are configured as cell bypass switching electronics components. Further, the terminals are electrically coupled to a junction between two energy storage units.

The battery system 100 includes a circuit module 102 for coupling to a plurality of battery cell units 104. For exemplary purpose, the battery system 100 includes six battery cell units 104a, 104b, 104c, 104d, 104e, 104e, 104f. However, any suitable number of battery cell units 104 may be used in the battery system 100. The battery system 100 includes battery pack terminals 101 and 103 for providing electrical energy to an external load or receiving electrical energy from an external supply (not shown).

The circuit module 102 includes six sets of terminals 106-116 for coupling with the battery cell units 104, each terminal set having a positive terminal 106a, 108a, 110a, 112a, 114a, 116a, and a corresponding negative terminal 106b, 108b, 110b, 112b, 114b, 116b. Each terminal set 106-116 is configured for coupling to a battery cell unit 104 (herein referred to as an associated battery cell unit 104). However, a person skilled in the art would understand that any number of terminals and battery cell units may be used in the battery system 100 or any of the battery systems described herein without departing from the scope of the invention.

In the battery system 100, the components of circuit module 102 are arranged in such a way that a positive terminal of one set of terminals 106a, 110a, 114a is directly coupled to the negative terminal of an adjacent set of terminals 108b, 118b, 116b by a conductor 118a-118c.

The negative terminal 106b of a first set of terminals 106 is coupled to a switching assembly 120a. Switching assembly 120a includes a first switch 122 for connecting battery cell unit 104a to the circuit module 102 when closed, and a second switch 124 for bypassing battery cell unit 104a when closed. More particularly, battery cell unit 104a is active or connected to the circuit module 102 when the first switch 122 is closed and the second switch 124 is open, and the battery cell unit 104a is inactive or bypassed from the circuit module 102 when the first switch 122 is open and the second switch 124 is closed.

Similarly, the positive terminal 108a of a second set of terminals 108 is coupled to a second switching assembly 120b. Switching assembly 120b includes a first switch 126 for connecting battery cell unit 104b to the circuit module 102 when closed, and a second switch 128 for bypassing battery cell unit 104b when closed. More particularly, battery cell unit 104b is connected to the circuit module 102 when the first switch 126 is closed and the second switch 128 is open, and the battery cell unit 104b is bypassed from the circuit module 102 when the first switch 126 is open and the second switch 128 is closed.

Accordingly, current flowing through battery cell unit 104a is controlled via the switches 122, 124. If switch 122 is closed and switch 124 is open, then any current flowing between pack terminals 101, 103 flows through switch 122 and battery cell unit 104a. If switch 122 is open and switch 124 is closed, then any current flowing between pack terminals 101, 103 passes through switch 124, but does not pass through battery cell unit 104a. Other battery cell units 104b-104f are controlled in a similar fashion via their associated switch assemblies.

The circuit layout including the two sets of terminals 106, 108, and the associated switching assemblies 120a, 120b respectively forms a single circuit unit block 131a of the battery system 100. The battery system 100 includes a further two circuit unit blocks 131b, 131c which are arranged in the same manner as unit block 131a. The three circuit units 131a, 131b, 131c are coupled together to form the overall system 100. However, it is understood that the system 100 may include any suitable number of unit block 131 to meet energy storage requirements of the specific application at hand.

As described, the positive terminal 106a for battery cell unit 104a is directly connected to the negative terminal 108b for battery cell unit 104b. Arranging the circuit in this way allows switches 122, 124, 126, 128 to be located in close physical vicinity on one side of the battery cell units 104a, 104b without the need to extend the length of the current path length between battery cell units 104 and the switches 122, 124, 126, 128. This advantageously results in reduced manufacturing costs, decreases space requirements, and avoids additional resistance, and thus energy losses caused by increased current path length.

However, in the battery system 100, to connect the positive terminal 106a for battery cell unit 104a to the negative terminal 112b of 104d through battery cell units 104b and 104c, the current passes through two switches 126, 130. In this embodiment, if all six battery cell units 104a-104f are to carry current, then the current also must pass through switches 122, 126, 130, 134, 138 and 142. This corresponds to current passing through one switch per cell unit, each of which has an on resistance and associated energy loss.

The arrangement of bypass switches shown in FIG. 4 are exemplary and other arrangements of cell and units bypass switches configured and operable to bypass any one or more cell units are possible. Further example circuits are shown within publications US20190363311A1, US20200144830A1 and U.S. Ser. No. 10/573,935B2, said circuits hereby incorporated into this specification by reference.

FIG. 5 shows a cross-section of the exemplary electronic assembly of FIGS. 1 and 3. The depicted embodiment has four or more layers, which are characterized from top to bottom: (1) thin conductive (part of flex circuit), (2) thin non-conductive (part of flex circuit), (3) thin conductive (part of flex circuit), (4) support layer (stiffener). In this exemplary embodiment, the first to third layers form the electronics board and in particular the terminal coupling region of the board. The fourth layer is a support layer which is arranged to border the region where the terminal contacts the electronics board. The (1) thin conductive layer has the function of carrying current within the electronic assembly. The (2) thin non-conductive layer has the function of in certain locations electrically isolating the (1) thin conductive and (3) thin conductive layers. The (3) thin conductive layer has the function of carrying current within the electronic assembly. The (4) thick support layer is electrically conductive or non-conductive, or has a combination of conductive and non-conductive regions, and in some embodiments is intended to improve the mechanical rigidity to the electronic assembly. Where the (4) support layer is conductive, the layer may additionally have the function of carrying current within the electronic assembly.

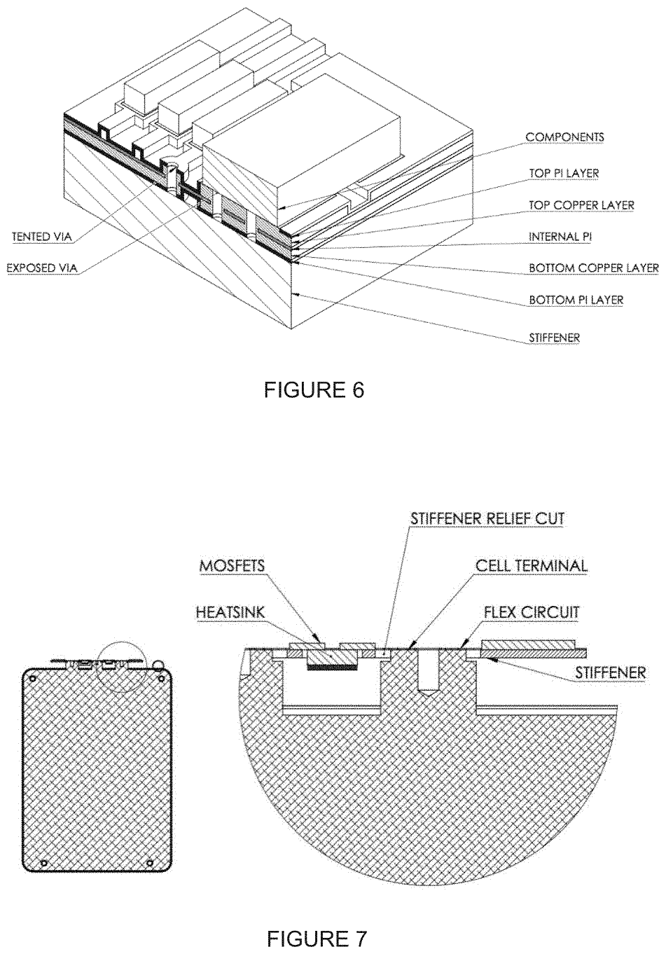

FIG. 6 shows a detailed sectional view of an exemplary embodiment of an electronic assembly with different layers. The electronic assembly has components as well as six layers, which are characterized in the following order from top to bottom: (1) thin non-conductive layer (“PI—polyimide—layer”) (2) thin conductive, (3) thin non-conductive (“PI layer”), (3) thin conductive, (4) thin non-conductive (“PI layer”) and (5) thick support layer (“stiffener”). The (1) thin non-conductive layer has the function of providing electrical isolation between the (2) thin conductive layer and the outside world. The (2) thin conductive is configured to carry current within the electronic assembly. The (3) thin non-conductive layer is configured to electrically isolate regions of the (2) thin conductive and (4) thin conductive layers. The (4) thin conductive layer is configured to carry current within the electronic assembly. The (5) thin non-conductive layer is configured to electrically isolate the (4) thin conductive layer and the surrounding environment. The (6) support layer may be electrically conductive or non-conductive or have a mixture of conductive and non-conductive areas and is configured to provide mechanical rigidity to the electronic assembly. This embodiment further has electronic vias, which form conductive vertical connections between two or more conductive layers. The vias may be large in number and/or size and/or density so as to achieve a desired thermal conductivity between two or more conductive layers, and may allow thermal energy generated by any components connected to one conductive layer to be distributed and effectively dissipated.

FIG. 7 shows an exemplary embodiment of an electronic assembly which has conductive and non-conductive layers, and a heatsink element. The heatsink element is configured to provide thermal exchange between the electronic assembly and other media such as ambient air, other gas and/or liquid cooling system which may be integrated within the end application. In this embodiment, the heatsink element consists of aluminum and does not have any moving components. In other embodiments, the heatsink element may be active and include a fan or other moving components. In some embodiments, the heatsink element may be made of other materials, such as materials suitable to high thermal transfer. In some embodiments, the heatsink element may include or connect to heat pipes or other thermal transfer arrangements.

In this embodiment, the support layer has a slit and a heatsink element is connected to the electronic assembly at the slit on the opposite side of electronics components. The heatsink element may alternatively be located on the same side as electronics components, or on the same or opposite side of other potential sources of heat generation.

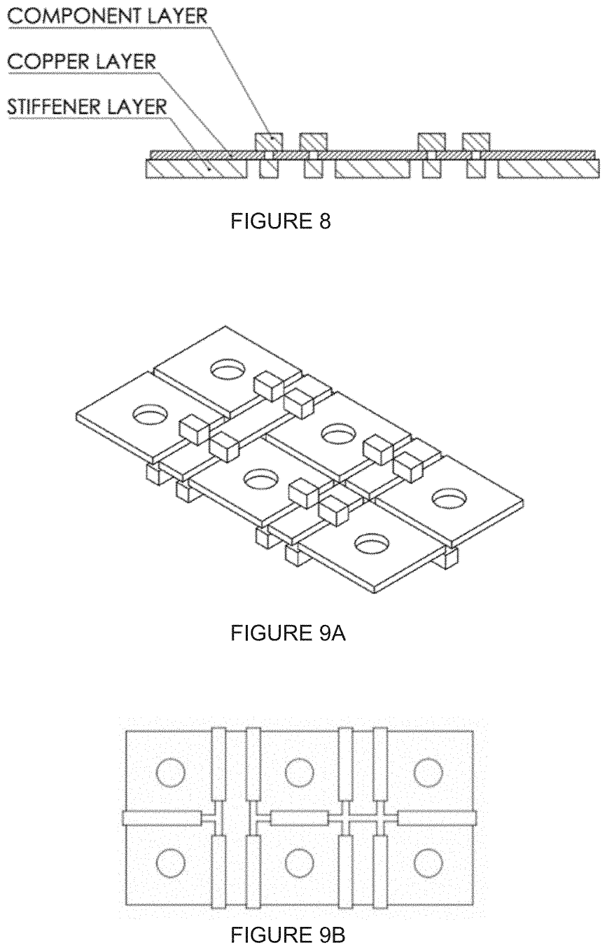

FIG. 8 shows an exemplary embodiment of an electronic assembly, FIG. 9A shows a top isometric view of the assembly, and FIG. 9B shows a bottom view of the assembly.

The exemplary embodiment of FIG. 8 is an electronic assembly comprising electronics boards adapted to span between multiple terminals of energy storage units. The terminals are arranged in a predetermined geometrical alignment and configured as a primary path of electrical current to or from the energy storage units. The electronics boards comprising terminal coupling regions configured as a primary path of electrical current between the electronics board and the unit terminals, and circuit regions comprising at least a first conductive layer and a second non-conductive layer. At least one part of the terminal coupling regions and/or at least one part of the circuit regions is characterized by a mechanical bending characteristic so as to permit at least some displacement from the predetermined geometrical alignment and/or a combined thickness characteristic. The electronics boards are either a number of separate boards arranged to span over the geometrical area defined by the unit terminals, the separate boards may be defined by discrete sections of boards, or, defined by gaps in the boards so as to define board areas between those gaps. Further, one or more support layers are provided to the electronics boards to as to increase the mechanical bending characteristic and/or a combined thickness characteristic of the boards in the region proximate the location of the support layers.

In some embodiments, the gaps in the board are spanned by one or more support layers. In this way, some mechanical displacement of the terminal coupling regions is permitted, but a region of the boards where a support layer is provided has increased rigidity to support application of discrete components in that location of the board.

The electronics assembly is a dual layer electronic assembly which is adapted to attach to three battery cell units, each having one positive and one negative terminal for connection to the electronic assembly. The electronic assembly comprises one conductive layers adapted to support electronic components and a support layer providing mechanical rigidity to the components and maintaining spacing between different sections of the conductive layer. The layers of the assembly are characterized by the abovementioned measure of bending and/or the combined thickness. The conductive layer of the electronic assembly is configured to carry current within the electronic assembly and to or from the terminals. A rigid non-conductive support layer is located underneath the conductive layer. The conductive layer has gaps which may be formed by slots or cut-outs. Beneath some or all of those gaps a support layer is located. In some embodiments, the support layer is configured to span and separate different regions of the conductive layer. In some embodiments, the conductive layer one or more gaps that are spanned by one or more electronic components.

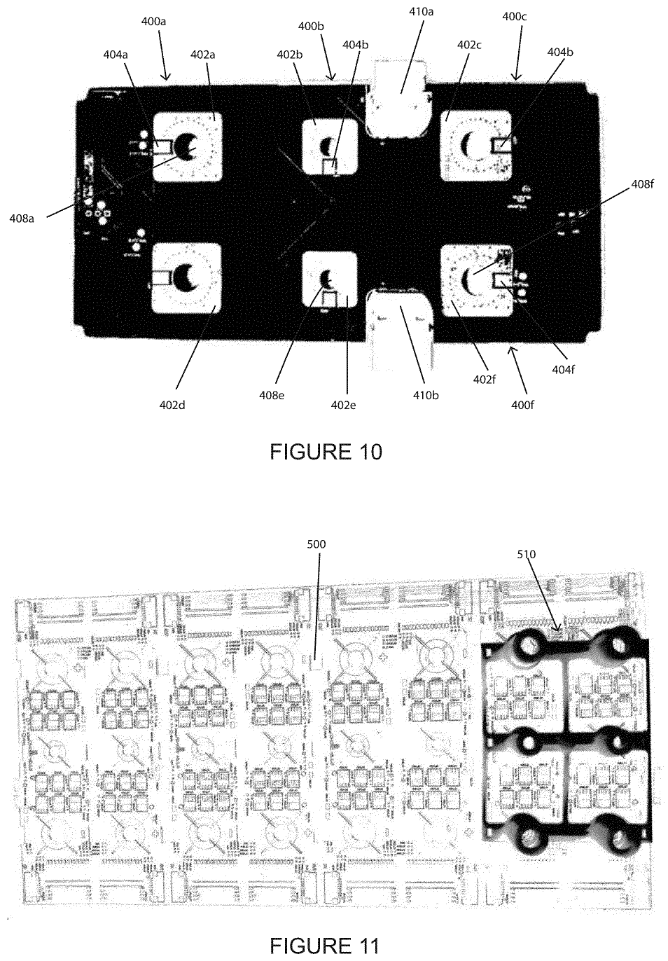

FIG. 10 shows a bottom view of another exemplary electronics assembly having conductive outer regions 400a-400f which comprise the terminal coupling regions of this example. The electronics assembly is adapted to attach to two battery modules, each having two series battery cell units with one positive terminal of one cell unit connected to the negative terminal of another cell unit and sharing one connection point 402b, 402e, respectively, to the board.

The exemplary embodiment comprises one or more electronics boards adapted to span between multiple terminals of energy storage units, the terminals are arranged in a predetermined geometrical alignment and configured as a primary path of electrical current to or from the energy storage units. The electronics boards comprising terminal coupling regions configured as a primary path of electrical current between the electronics board and the unit terminals, and circuit regions comprising at least a first conductive layer and a second non-conductive layer. Further, at least one of the terminal coupling regions comprising conductive segments, a segment configured as a measurement pad, and a segment configured as the primary current path.

Each of the terminal coupling regions 400a-400f have a segment 404a-404f configured for measurement which is electrically isolated from other segments 402a-402f of the terminal coupling region. Isolation is provided in this example by the layout of the conductive layer of the electronics board. However, other exemplary embodiments employ other methods of segmenting the terminal coupling region such as by provision of physical gaps in the electronics board in the location of the terminal coupling region.

The separate measurement segments 404a-404f each define a measurement pad. When not connected to a battery cell unit, the measurement pad is isolated from other segments of the terminal coupling region. In the example shown, the large conductive area 402a-402f of each terminal region is configured to enable the main current flow between the electronic assembly and the connected battery cell units whereas the small conductive area 404a-404f near each terminal may be used for voltage and/or temperature measurement.

By separating the contact area experiencing main current flow 402a-402f from the contact area for measurement 404a-404f, it may be possible to take more exact measurements, such as of cell unit voltage and/or cell unit temperature. In some embodiments, it is possible to conduct two or more cell unit voltage measurements, including at least one in an area experiencing main current flow 402a-402f and another in an area separated from the main current flow 404a-404f. Comparing such two measurements may provide a measurement of contact resistance, including while a battery cell unit is under load.

The terminal coupling regions also include an aperture 408a-408f configured to allow pass-through of a fastener device to mechanically secure the terminal coupling region, and the electronics board, to a cell terminal.

In some embodiments, the terminal coupling regions has exposed areas of conductive material near the terminal attachment point which further include vias, which form conductive vertical connections between two or more conductive layers. In some embodiments, the number of vias in the electronics assembly may be up to 1, 5, 10, 1000 or 10000, or a different number. In some embodiments, some areas may have vias at a density of up to 1/cm2, 10/cm2, 100/cm2, 1000/cm2 or a different spatial density of vias.

This embodiment also shows connectors 410a-410b configured to allow connections to other electronics boards, to one or more electrical supplies, electrical loads, inverter circuitry such as h-bridge circuits, or other circuitry or external devices.

FIG. 11 shows another exemplary embodiment of an electronics assembly. The assembly has a single electronics board 500 adapted to span over a geometrical location of many cell terminals, shown here as eight battery modules, each having two series battery cell units, and the one positive terminal of one cell unit connected to the negative terminal of another cell unit and sharing one connection point to the board.

The electronic assembly has a fastener retainer device 510 adapted to maintain the fasteners used to attach the board to the in position even when not fastened to cell modules. This has several advantages including facilitating disassembly and reassembly of an electronic assembly to modules. The fastener provides an additional function of substantially enclosing, and therefore limiting risk of any external contact with, exposed conductive material, such as related to any parts of a fastener assembly. In this embodiment, the retainer device 510 is a plastic cage around the bolts, which clips into slits on the board. In other embodiments, other captive fastener arrangements may be used for a similar purpose.

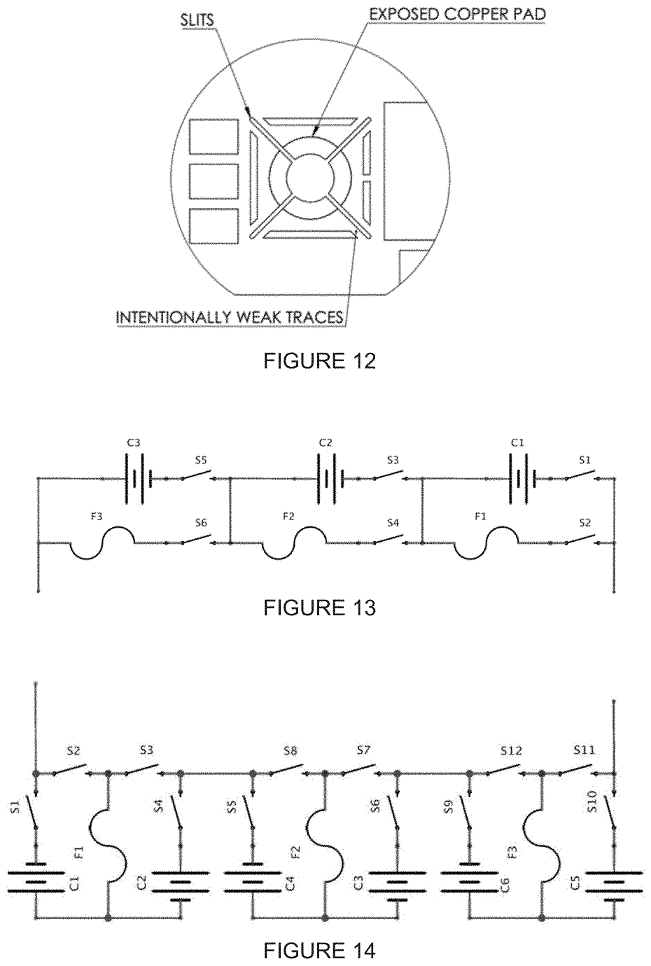

The depicted assembly further includes optional recesses arranged to segment the terminal coupling regions as will be explained further with reference to FIGS. 12-14 below.

The exemplary embodiment of FIG. 11 is an electronic assembly comprising one or more electronics boards adapted to span between multiple terminals of energy storage units, the terminals are arranged in a predetermined geometrical alignment and configured as a primary path of electrical current to or from the energy storage units. The electronics boards comprise terminal coupling regions configured as a primary path of electrical current between the electronics board and the unit terminals, and circuit regions comprising at least a first conductive layer and a second non-conductive layer. Further, a fastener retainer cage is adapted to maintain one or more fasteners in alignment with the terminal coupling region.

FIG. 12 shows a close up view of an exemplary electronic assembly, and in particular, a terminal coupling region. The terminal coupling region has an aperture to allow pass-through of a fastener to connect the assembly to a terminal of at least one battery cell unit. In this embodiment, the fastener such as a bolt, nut and/or any washer employed, is conductive and be able to carry current between the electronic assembly and the one or more battery cell units. However, in varied embodiments, the fastener may be non-conductive and the main current carried by other means, such as contact of conductive areas between the board and a cell unit, or other conductive material between these.

As in the embodiment above, the electronic assembly has an area of exposed metal in the vicinity of the aperture, to create a low-resistance contact with an adjacent battery cell unit terminal, the nut, bolt, and/or washer.

The terminal coupling region comprises a conductive pad segmented by an arrangement of physical slits to all of the layers of the electronic assembly. However, in varied embodiments, the slits may apply only to some but not all layers of the electronic assembly. A first kind of slit that connects to the hole and runs diagonally outward. These slits may provide additional mechanical flexibility when connecting to one or more terminals of one or more battery cell units that may or may not be well-aligned. In addition, these slits may create two or more areas of exposed metal that are electrically isolated from one-another when not connected to a battery cell unit. One or more such areas may be used to enable the main current flow between the electronic assembly and the connected battery cell units. One or more other such areas may be used for the measurement pad for voltage and/or temperature measurement. By separating the contact area experiencing main current flow from the contact area for measurement, it may be possible to take more accurate measurements, such as of cell unit voltage and temperature.

In some embodiments, the cuts outs are defined by slits arranged to create a narrowed conductive trace in the first conductive layer. The narrowed trace is intentionally weakened by this narrowing or relatively narrowed dimension and thereby defines the abovementioned fuseable circuit. The fuse is ideally located between one more connection points with battery cell units and one or more other connection points either with one or more battery cell units, optional electronics components, power supplies and/or electrical loads. These intentionally weak traces may be designed such that upon particularly high currents, one or more layers of the material melt or otherwise react in such a way that the trace connection significantly or entirely decreases in electrical conductivity. This may allow the electronic assembly in this embodiment to integrate the function otherwise provided by fuse components, which may avoid associated component cost. The material of some layers such as non-conductive layers may be chosen to have a high melting point, such that melted conductive material may be prevented from expelling from the electronics boards.

In some embodiments, the cut outs are arranged to reduce the thermal conductivity between the electronic assembly at a connection point to one or more cell units and other areas of the electronic assembly. For example, this may reduce the thermal conductivity between the connection point of a battery cell unit and electronics components connecting to the electronic assembly which may during operation display a certain level of heating. Resultantly, this may reduce the heat energy passed to a connected battery cell unit, which may increase longevity of such a battery cell unit. This may also reduce the heat energy passed to one or more temperature sensors placed at or near a battery cell unit connection point, which may in turn allow the temperature sensors to measure a temperature that may be more similar to the temperature of the inside of a battery cell unit.

The exemplary embodiment of FIG. 12 is an electronic assembly comprises one or more electronics boards adapted to span between multiple terminals of energy storage units, the terminals are arranged in a predetermined geometrical alignment and configured as a primary path of electrical current to or from the energy storage units. The electronics boards comprising terminal coupling regions configured as a primary path of electrical current between the electronics board and the unit terminals, and circuit regions comprising at least a first conductive layer and a second non-conductive layer. At least one of the terminal coupling regions comprises conductive segments, a segment configured as a measurement pad, and a segment configured as the primary current path, wherein the conductive segments are defined by one or more cuts outs having a depth or at least the first conductive layer.

In some embodiments, the cut outs are configured to define the abovementioned measure of the mechanical bending characteristic. In some embodiments, the electronic board comprises a heat generating component, and the cut outs are located between a heat generating component and the terminal coupling region so as to limit thermal energy transfer between the heat generating component and the terminal coupling region.

FIG. 13 shows an exemplary electronics circuit assembly for placement on a circuit board. The assembly has a predetermined geometrical alignment and/or a combined thickness characteristic as would be optimized for the arrangement of connected cells. The circuit also has electronics components in form of switching components S1-S6 disposed in the primary current path of cells C1-C3. The circuit also has further includes a fuseable circuit F1-F3. Each fuseable circuit protects against a short circuit in case of a failure or mistaken operation of one or more switching components. For example, if switch component S1 fails short and switch component S2 closes, then the short circuit seen by cell unit C1 will be prevented by fuseable circuit F1. In this example, the fuseable circuit is connected in the bypass path for cell unit C1.

FIG. 14 shows an example electronics circuit for implementation on any of the described electronics assemblies having a predetermined geometrical alignment and/or a combined thickness characteristic. The assembly has a terminal which is electrically coupled to a junction between two energy storage units. A fuseable circuit F1 is connected to a terminal coupled between the junction between cell units C1 and C2. In this example, only one fuseable circuit is required to protect against a short circuit in case of a closed-circuit failure of any one switching component for two cell units. For example, if switch component S1 fails short and switch component S2 closes, then the short circuit seen by cell unit C1 will be prevented by fuseable circuit F1. In a different scenario, if switch component S3 fails short and switch component S4 closes, then the short-circuit seen by cell unit C2 will be prevented by fuseable circuit F1. This electronics assembly may there have the advantages of needing fewer fuseable circuits than electronics assemblies having one or more fuseable circuits per cell unit, which may reduce component cost. This circuit may further have the advantage of having no fuseable circuits included in the current flow when all cell units are connected, which may increase efficiency. This circuit may further have the advantage of having no fuseable circuits included in the current flow when all cell units are bypassed, which may avoid increased resistance in the bypass path.

In some embodiments, which may have one, two or more cells firmly connected in series, and switching components to selectively bypass and reversible disconnect one or more cell units, there is at least one fuseable circuit for each cell unit. In some embodiments, the fuseable circuit for each cell unit is located in the bypass path of a battery cell unit, which may have the advantage of reducing losses in the electronics assembly when the battery cell unit is connected in series. In other embodiments, this fuseable cell circuit is located directly in series with a battery cell unit, which may have the advantage of reducing losses in the electronics assembly when the battery cell unit is bypassed.

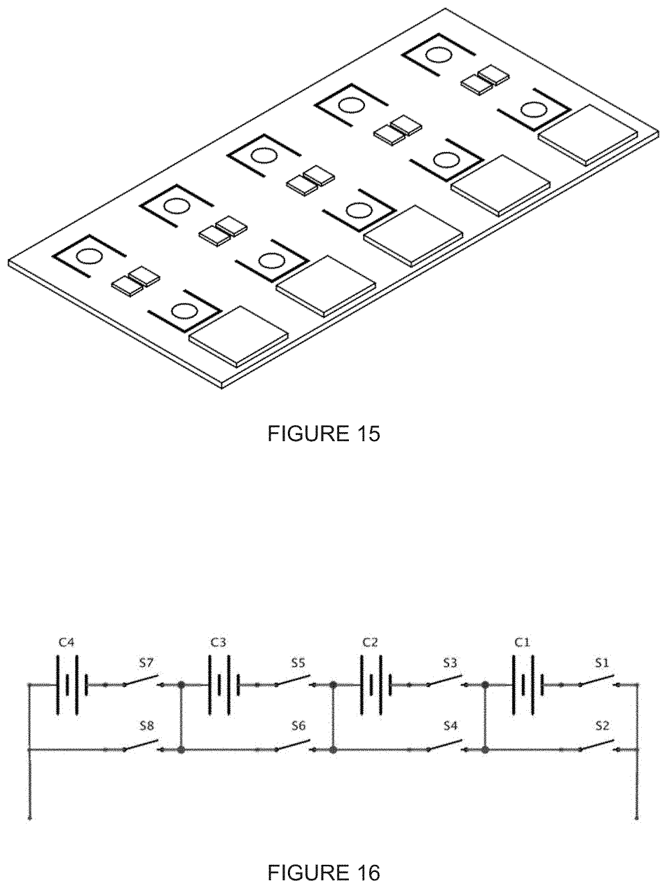

FIG. 15 shows a top view of an exemplary embodiment of an electronic assembly where a single electronics board is adapted to span between multiple cell unit terminals. In particular, five battery cell units each have one positive and one negative connection point to the electronic assembly. In this embodiment, the electronic assembly has conductive terminal coupling regions with areas (shown having a round shape, but may be square or any other shape) intended for creating a welded connection to one or more terminals of battery cell units. This may for example be achieved by capacitive discharge resistance welding, laser welding or ultrasonic welding, and may further use a separate tab conductor as part of the connection.

In this exemplary embodiment, the terminal coupling regions are defined by slits near the points of connection. In this embodiment, these slits are straight lines on three sides of the connection passing through all layers of the electronic assembly. However, varied embodiments may implement the slits as curved lines, or may be fully or partially along any number of sides, for example two sides. These slits act to focus any mechanical stress imparted to the assembly by movement and/or misalignment of the cell units to the region of the board located between edges of the slits. That region of the board acting as a hinge or otherwise to provide additional mechanical flexibility when connecting to battery cell units.

The exemplary embodiment of FIG. 15 is an electronic assembly comprising one or more electronics boards adapted to span between multiple terminals of energy storage units, the terminals are arranged in a predetermined geometrical alignment and configured as a primary path of electrical current to or from the energy storage units. The electronics boards comprising terminal coupling regions configured as a primary path of electrical current between the electronics board and the unit terminals, and circuit regions comprising at least a first conductive layer and a second non-conductive layer. Further, at least one of the terminal coupling regions is defined by an arrangement of one or more cut outs in the one or more electronics board so as to define a region of attachment of the terminal coupling region and the circuit region of the board; and wherein the region of attachment defines the mechanical bending characteristic and/or a combined thickness characteristic of the boards.

FIG. 16 shows an example of an electronic circuit for implementation on the any of the electronics assemblies having a predetermined geometrical alignment and/or a combined thickness characteristic, the circuit includes electronics components in the form of switch components attached to four battery cell units, each having one positive and one negative terminal connecting either directly or via circuitry to the electronics assembly. The switch components are operable to selectively bypass and reversibly disconnect one or more energy storage units. For example, when switch components S1, S3, S5 and S7 are closed and all other switches open, then switch components S1, S3, S5 and S7 are disposed in the primary current path and cell units C1-C4 are electrically connected in series with one another and with the circuit output terminals shown. If subsequently, switch component S1 is opened and switch component S2 is closed, then switch component S2 becomes disposed in the primary current path and cell unit C1 is selectively bypassed and reversibly disconnected from the series arrangement with the other cell units and the output. Similarly, each of cell units C2-C4 can be selectively bypassed and reversibly disconnected, by opening and closing the corresponding switches. Multiple cell units can be selectively disconnected from the arrangement at one time.

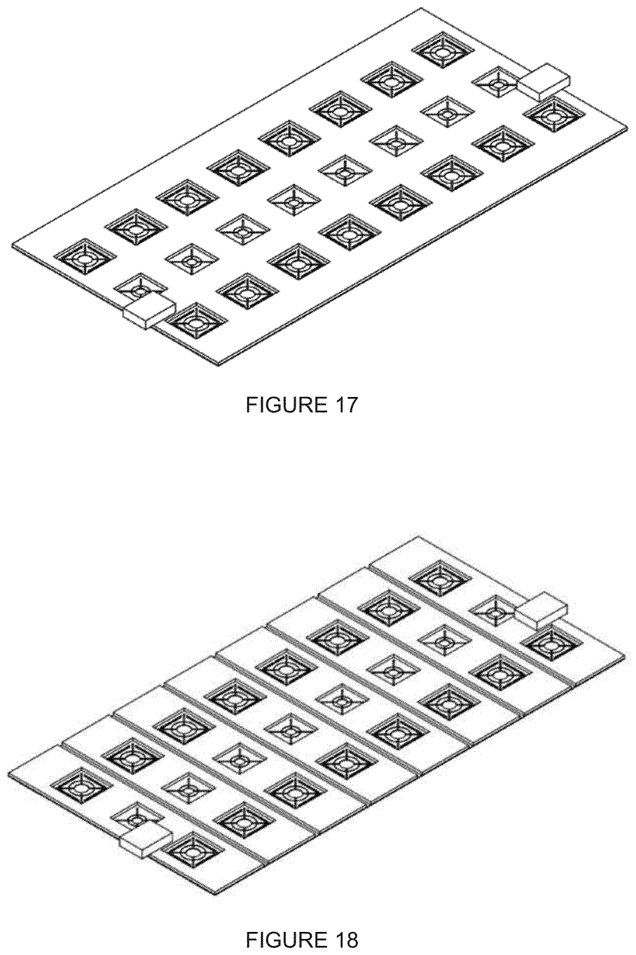

FIG. 17 shows the bottom isometric view of an exemplary embodiment of the bottom of an electronics assembly which has one or more cut-outs in one or more layers in the area where one or more cell units connect to the electronic assembly. These cut-outs may apply to layers that include comparatively rigid layers. Where a comparatively rigid layer has any cut-outs, this may allow the electronic assembly to have additional mechanical flexibility near the connection point to battery cell units. This may allow the electronic assembly to connect to one of more battery cell units with connection points that may move or not be well-aligned in one plane without causing undue stress in the electronic assembly or any optional electronics components or electronics elements.

Additional mechanical flexibility may further enable the electronics assembly to better mold to the shape of the cell unit contract to be connected to, which may reduce electrical contact resistance and improve operational efficiency. It may also enable the shaping of the electronic assembly to the shape and contours of battery modules, including to accommodate for ridges or other heightened parts of battery modules that may be raised compared to the plane of cell unit connection points. The mechanical flexibility in electronics boards may further be employed to increase the surface area of an electronics board between two fixed points for example by forming approximately a wave shape, such as a square wave or a sine wave, which may be used to enable integration of additional electronics components and/or to increase thermal dissipation. Furthermore, additional mechanical flexibility may also dampen vibrations, for example between connected cell units and the electronic assembly.

This embodiment may have four or more layers, which may be characterized in the following order from top to bottom: (1) flexible conductive, (2) flexible non-conductive, (3) flexible conductive, (4) rigid. In some embodiments, there may be an additional flexible non-conductive layer between the (3) flexible conductive and (4) rigid layers. In some embodiments, there may be an additional flexible non-conductive layer on top of the (1) flexible conductive layer.

In some embodiments, one or more flexible conductive layers may comprise aluminum or copper. In some embodiments, one or more flexible non-conductive layers may comprise of polyimide, KAPTON® tape, polyethylene terephthalate, or polyethylene naphthalate. In some embodiments, one or more rigid layers may comprise of glass-reinforced epoxy laminate or aluminum.

FIG. 18 shows the bottom view of another exemplary embodiment of the electronic assembly with cut-outs at points of attachment to a cell unit. The electronic assembly also has cut-outs in one or more areas other than at the points of cell unit connection. These areas may align with the plane where at least two battery modules border one-another. These cut-outs may apply to layers that include comparatively rigid layers and may be such that all remaining layers in the area of cut-out may be comparatively flexible layers. Where a comparatively rigid layer has one or more cut-outs and these cut-outs align with the plane where two battery modules border, this may allow the electronic assembly to have additional mechanical flexibility to enable connecting without stresses to two battery modules that may have some misalignment in one or more directions

In some embodiments, the flexible layer is implemented with KAPTON® or polyimide tape, and spans the assembly. The flexible layer is laminated with comparatively rigid layers of electronics board to define support regions. The flexibility may be such that that the combination of all layers present at one or more locations are defined by the abovementioned mechanical bending characteristic.

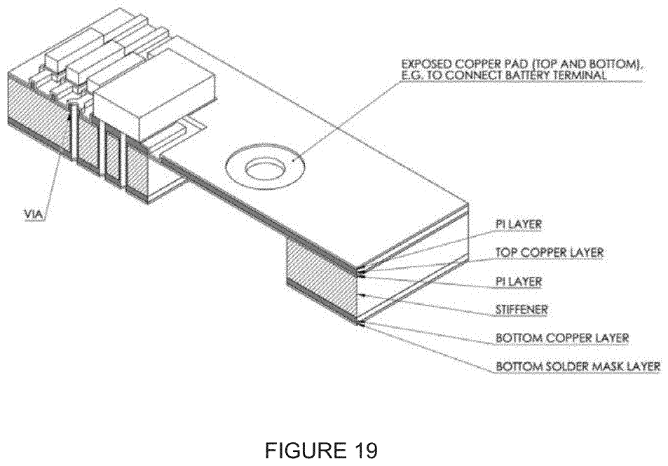

FIG. 19 shows an exemplary embodiment of an electronic assembly an electronics board laminate of six layers, the board also supporting electronic components. The layers are characterized in the following order from top to bottom: (1) flexible and thin non-conductive layer (“PI—polyimide—layer”) (2) flexible and thin conductive, (3) flexible and thin non-conductive (“PI layer”), (4) support layer, (5) flexible and thin conductive, and (6) thin non-conductive layer (“solder mask”).

The (1) thin non-conductive layer may have the function of providing electrical isolation between the (2) thin conductive layer and the outside world. The (2) thin conductive layer may have the function of carrying current within the electronic assembly. The (3) thin non-conductive layer may have the function of providing electrical isolation between the (2) thin conductive layer and the outside world, particularly in areas where there is no (4) support layer. The (4) support layer may be electrically conductive or non-conductive or have a mixture of conductive and non-conductive areas and may have the function to provide mechanical rigidity to the electronic assembly. Where the support layer is conductive, it may have the function of carrying current, or improving thermal transfer from or between areas of the (2) thin conductive layer, the (5) conductive layer, and/or the outside world. The (5) conductive layer may have the function of carrying current within the electronic assembly. The (6) non-conductive layer may have the function of providing electrical isolation between the (5) conductive layer and the environment.

In varied embodiments, there may be two or more support layers. In other embodiments, there may be three, four or more conductive layers, which may or may not be thin and/or flexible. In some embodiments, there may also be layers of adhesive materials, such as glue, resin and/or reinforcing materials such as fiberglass cloth, which may increase adherence between different layers.

The following embodiments are exemplary implementations of electronic components which may be located between two conductive layers. In exemplary embodiments, the components are switching components such as transistors and are configured to electrically connect the layers as desired. In other embodiments, the components are connected to only one layer yet are embedded between layers. The conductive layers form, at least in part, the circuit region of the electronic assembly. Further, the conductive layers and electronic components may together form a primary path of electrical current between one terminal coupling region and another. The following embodiments are intended to be interpreted as a portion of a bigger circuit. However they may also be operated as sub groups. Some of these embodiments are intended to illustrate the principles of electronics board construction when embedding switch transistors for control of the primary current path connected with energy storage units.

Embodiments discussed herein show a circuit region which includes a vertical arrangement of conductive layers, optionally separated by one or more nonconductive layers, components or parts. The vertical overlap of the conductive layers may enlarge the conductive area of a circuit board and allow the layers to connect with electronic components which are configured to control the primary path of electrical current from one layer, through the component, to the next layer. Further, the vertically overlapping arrangement of conductive layers allows electrical components to be connected to both upper and lower layers thereby maximizing the use of surface area on an electronics board. This offers advantages over components which may be arranged on a single conductive layer and thereby that single layer to be divided into first and second regions connected by the components. Such arrangements therefore facilitate the use of more components, if desired, to lower the overall resistance of the primary path of electrical current. Components being disposed between, and connected to, two conductive layers also means that currents going through these components on one side of a board do not need to travel through at least one layer of traditional FR4 or other insulating materials (through vias) to get to another conductive layer on the other side of the board, as is often the case with a component surface mounted on a PCB. This helps reduce the overall resistance in the current path and also improves thermal conductivity. In some embodiments, these components are switch transistors for selectively bypass and reversibly disconnecting any one or more storage units.

Terminal coupling regions in the embodiments discussed below may be configured as part of the electronics assembly, such as a conductive layer on an electronics board which may extend from a circuit region of the board.

In other embodiments, the terminal coupling regions are a hybrid construction whereby the assembly includes one or more metal materials such as a busbar. The busbar may be layers with a conductive region of a board including the circuit region and/or the terminal coupling region. The additional layer may act to enhance the current carrying capacity of at least the terminal coupling region of the board, or it may act to strengthen the region, or both. For example, a busbar may be arranged as a support layer disposed between terminals and terminal coupling regions. In some cases where terminals are in the form of busbars, the copper busbars may act as both terminals and support layers. Busbars may also be layered on a conductive layer in any regions to provide the above-mentioned benefits.

In other embodiments, busbars are configured to connect with cell terminals as part of an electronics assembly. In turn, the busbars are connected with a conductive layer of an electronics board. The terminal coupling regions of the electronics assembly should in such cases be understood to mean the region of the electronics board where attachment to a rigid cell terminal, or cell terminal extension material is formed. In such cases, the cell terminal may be enlarged by such rigid connections to other materials and take the form of tabs, foils, busbars, buttons, posts and other constructions.

Preferred forms of the busbar referred to in this specification are copper extrusions. This will be readily understood due to the conductive properties of the material.

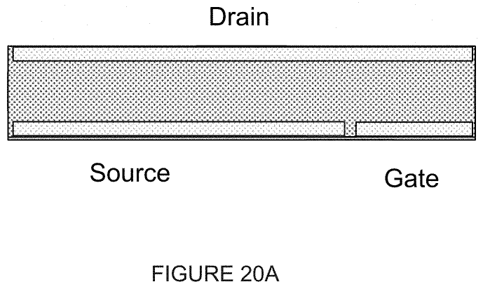

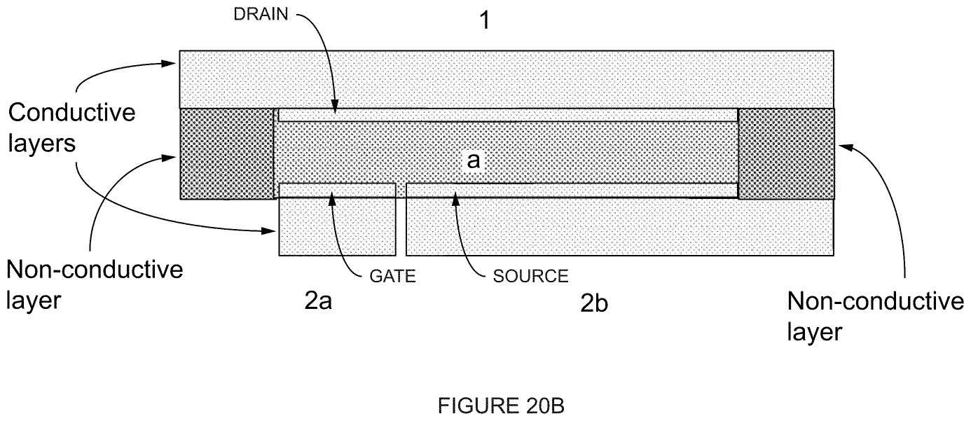

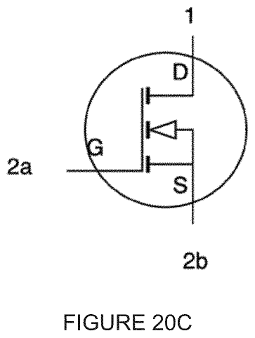

FIGS. 20A and 20C show an exemplary component package of a semiconductor switch where drain 1 and source 2b terminals are exposed metal surfaces, typically known as a tab or pad, and are distributed across opposing faces of the component body. The gate terminal may be located on any face, but preferably is located on one of either the drain or the source package face such as depicted. A component package of this kind is configured to connect with a laminate of conductors and operable to control the connection of the conductors, through the component, by appropriate control of the gate.

FIG. 20B shows an exemplary embodiment where the component body is located between an upper conductive layer and a lower conductive layer. Particularly that the upper layer connects with a drain terminal on the upper component face, and the lower conductive layer connects with the lower component face.

In some embodiments, the conductive layers are copper layers of a PCB (e.g. in the form of copper traces). In other embodiments any other conductive materials can be used to serve the same purpose such as aluminum. Combinations of conductive materials and PCB implemented traces are also possible.

In some embodiments, a non-conductive layer is also included in the laminate and is configured to separate the upper and lower conductive layers in regions of the laminate around a component. The non-conductive layer can be a thin material and/or may be a flexible material. Examples of suitable non-conductive layers include polyimide, KAPTON® tape, polyethylene terephthalate, or polyethylene naphthalate.

Operation of the embodiment shown in FIG. 20B is to facilitate current conduction from one conductive layer to the other, through the component. In one exemplary embodiment, the component is a MOSFET (NMOS) transistor. Other types of transistors can be used to similar effect. Current conduction from one layer to the other can be controlled by turning on the transistor. Similarly, electrical isolation of the upper and lower layer is controlled by turning off the transistor. Control is facilitated by the gate of the transistor component. For example, a controller may be configured to selectively signal the gate of the component to control conductivity of the component, and thereby control the connection and isolation of the upper and lower conductive layers.

Note that this is representative only to show the fundamental principles, there may be other layers that are not shown, such as support layers or additional conductive/non-conductive layers.

FIG. 20B therefore shows an electronic assembly comprising one or more electronics boards comprising a circuit region comprising at least a first conductive layer and a second conductive layer arranged in a laminate and separated by at least one electronic component. In some embodiments, the upper and lower conductive layers comprise terminal coupling regions, and therefore define a primary current path from one terminal coupling region, through the circuit region, and to the next terminal coupling region. The electronic component(s) are disposed in the primary current path and operate to, for example, configured to control current flow from one terminal coupling region to the next. In some embodiments, the components are configured to selectively bypass an energy storage unit and/or reversibly disconnect an energy storage unit. The components are configured to perform such operation by breaking and or redirecting the primary current path between any two terminal coupling regions.

In this embodiment, the upper conductive layer is preferably connected with a first energy storage unit, and the lower layer with a second unit. In this way, the conductive layers and the component form a series connection between units and together form a primary current path between those storage units.

Preferably at least one part of the terminal coupling regions and/or at least one part of the circuit regions comprising at least the conductive layers are characterized by a mechanical bending characteristic so as to permit at least some displacement from the predetermined geometrical alignment and/or a combined thickness characteristic.

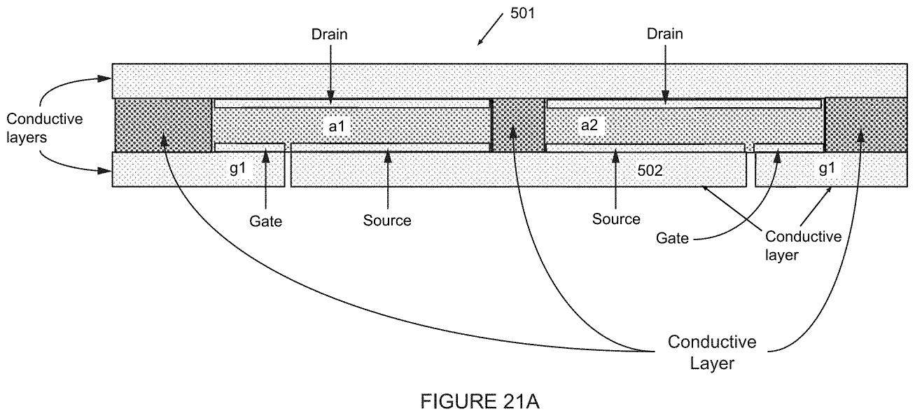

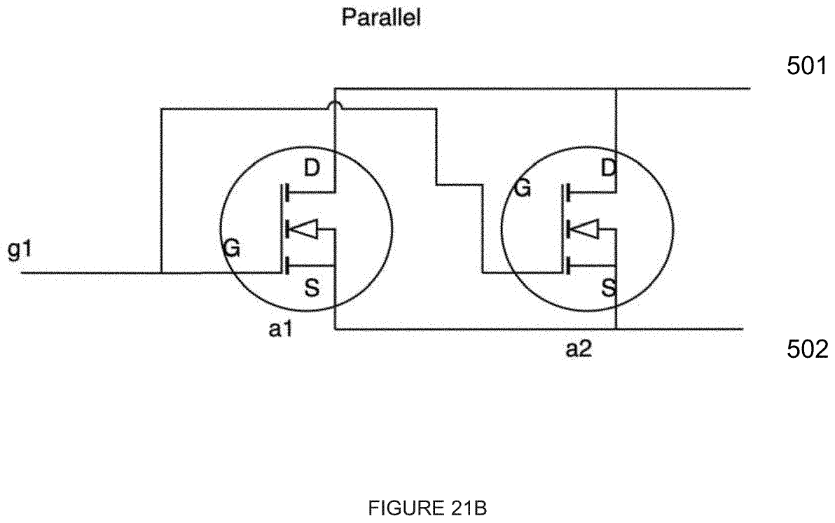

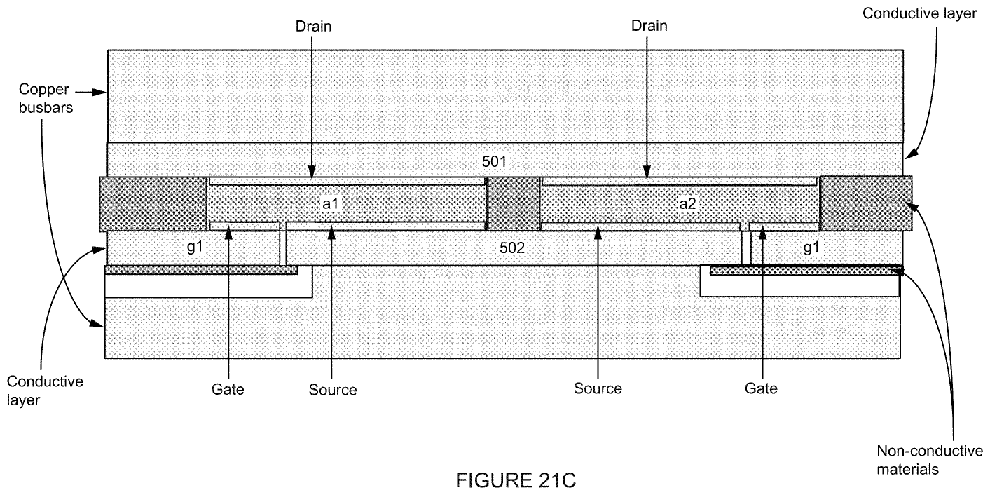

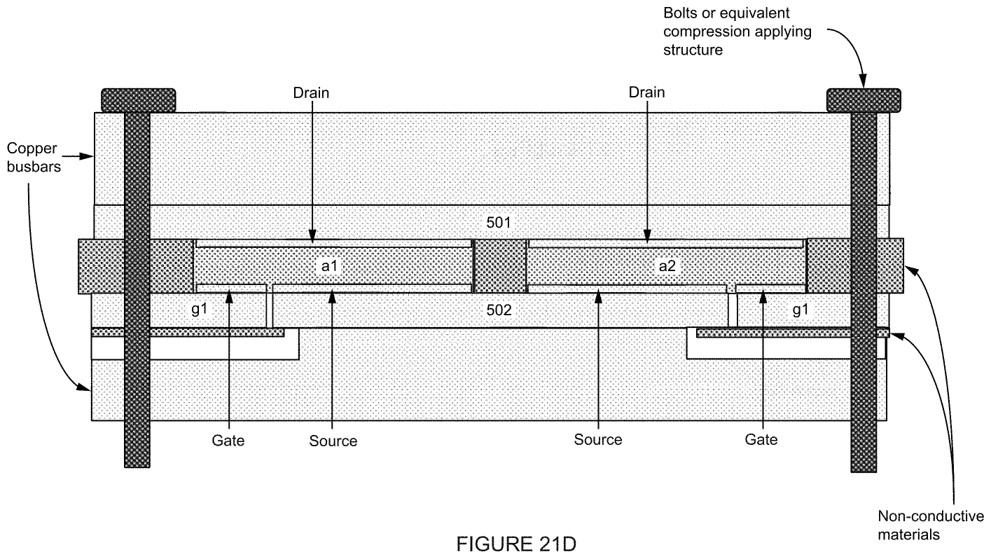

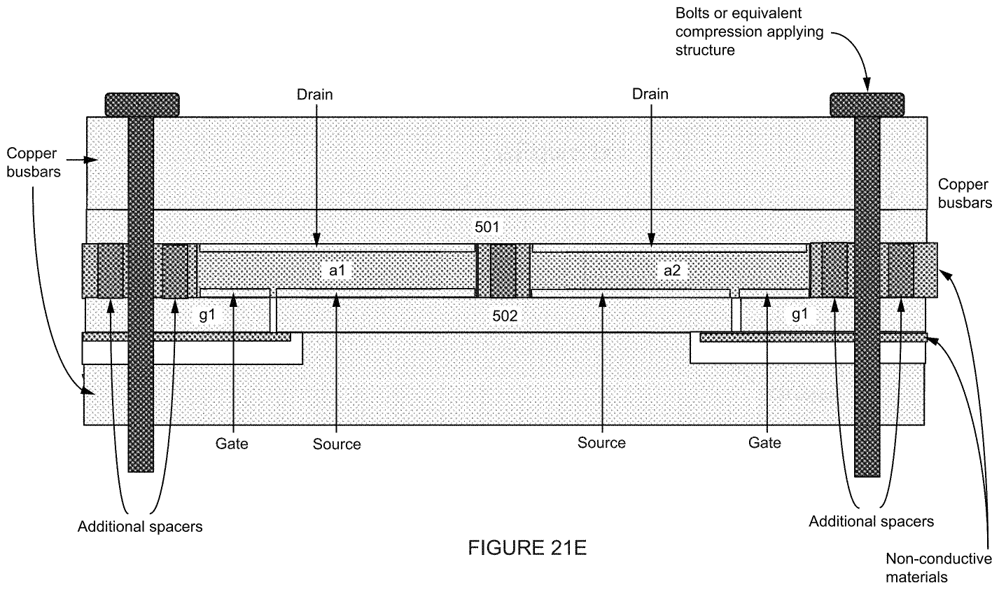

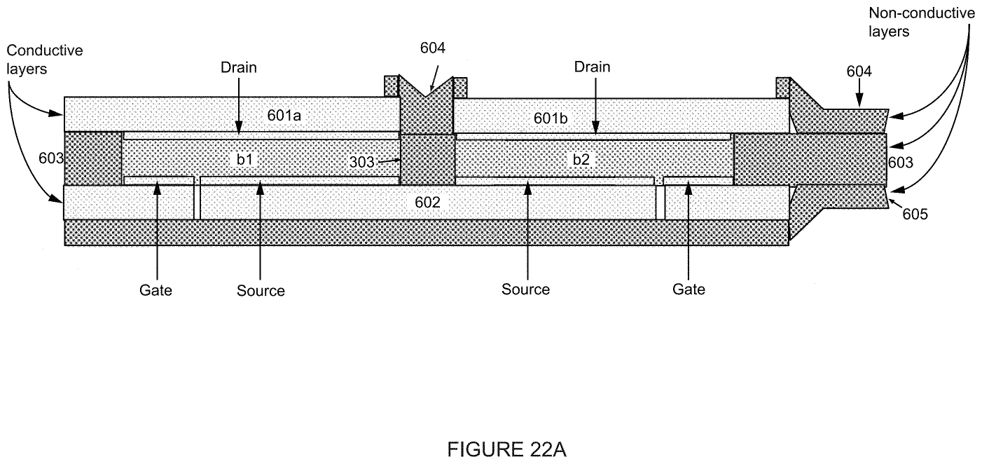

FIG. 21A shows a variation of the embodiments of FIG. 20 where two switching components are configured in parallel. Having two or more transistors connected in parallel collectively serves the same purpose of a single switch since multiple switch transistors connected in parallel collectively operate as a single switch. Transistors configured in parallel are advantageous for sharing electrical loads, improving conductivity, and enlarging thermal coupling of electrical losses to the environment. For example, parallel transistors off a reduction in the overall resistance in the current path through the collective switch. This leads to higher energy efficiency as the energy loss due to resistance will be lower. This benefit is even more significant at high currents. In some embodiments, 5, 10, 20, 50 or 100 transistors are connected in parallel.

FIGS. 21A and 21B show that the sources of both transistors a1 and a2 are connected together, the drains of both transistors are connected together, and the gates of both transistors are connected together at g1, to form a parallel circuit represented in FIG. 21b. Connection between gates is not shown in FIG. 21A but can be assumed consistent with the circuit diagram in FIG. 21B. In operation, when switch transistors a1 and a2 are turned on, a current can be conducted from the top conductive layer 501 to the bottom conductive layer 502. When switch transistors a1 and a2 are off, no current can be conducted between the two conductive layers 501 and 502.

FIGS. 21B and 21C show the two components configured in parallel and located between an upper conductive layer and a lower conductive layer. The components and at least part of the conductive layers together form a circuit region. The conductive layers may extend beyond the circuit region and, alone or together, form one or more terminal coupling regions configured for connection to energy storage units. In some embodiments, a non-conductive layer is also located between the upper and lower conductive layers to space the conductive layers apart in at least in the location of the components.

FIG. 21C also shows busbars which are located on top of and connected to the conductive layers. Busbars are typically constructed from rigid materials such as a thick metal bar or plate. The busbars depicted in this instance are layered above and below the upper and lower conductive layers respectively. The layering of conductive materials provide the conductive layers with an improved current carrying capacity and/or improve thermal dissipation and/or improve structural support. In preferred embodiments, the busbars are a highly conductive material such as copper. However any other conductive material may be used to conductive layers to suit any of the aforementioned improvements.

Note from FIG. 21C also that gaps in the conductive materials adjacent to the gates are needed to preserve electrical isolation of the gates g1 from other terminals.

In some embodiments non-conductive materials may be added to improve structural support in place of the busbars shown, or to supplement the busbars.

In some embodiments, the busbars are located over the board of the circuit assembly. In some embodiments, the busbars extend beyond the circuit region where the components are located, and form a terminal coupling region. In some embodiments, the busbars and electronics boards together form a terminal coupling region.

FIGS. 21D and 21E show the use of bolts or other fastening components which act to compress the layers of the electronic assembly together. In some embodiments, the spacers are provided to protect the structural integrity of the switch transistors such that compression forces are avoided or minimized from the switch components themselves. In some embodiments, insulating/non-conductive layers can be pre-compressed to protect the switch transistors such that the preload of the layer provides additional mechanical resistance from the compression force of the fasteners. In some embodiments, bolts or similar compression applying components can be used to provide compression for the same purpose.

In some embodiments, such as shown in FIG. 21E, additional spacers are added near or adjacent to switch transistors to provide additional protection in the region which is immediately proximate the components. Materials such as steel can be used for the bolts and/or spacers. But another material can be used as long as it compresses less than the switch transistors so that the purpose of protecting the transistors can be served.

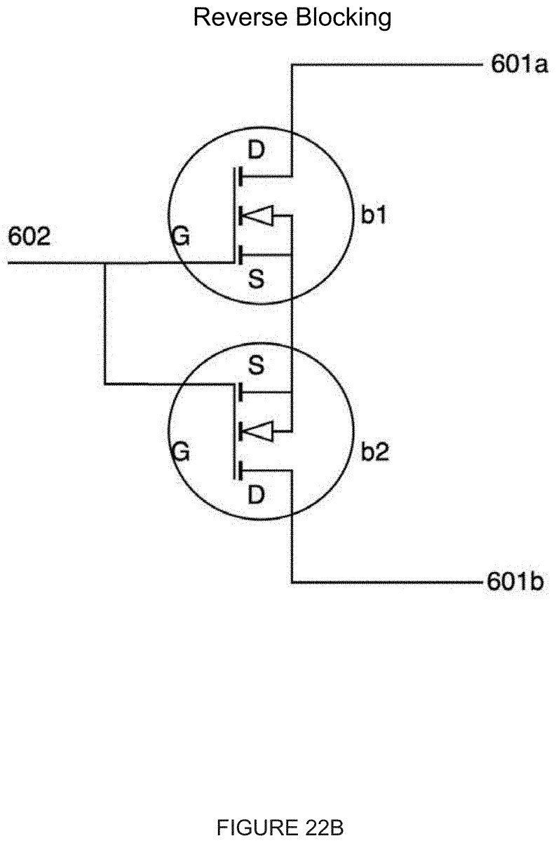

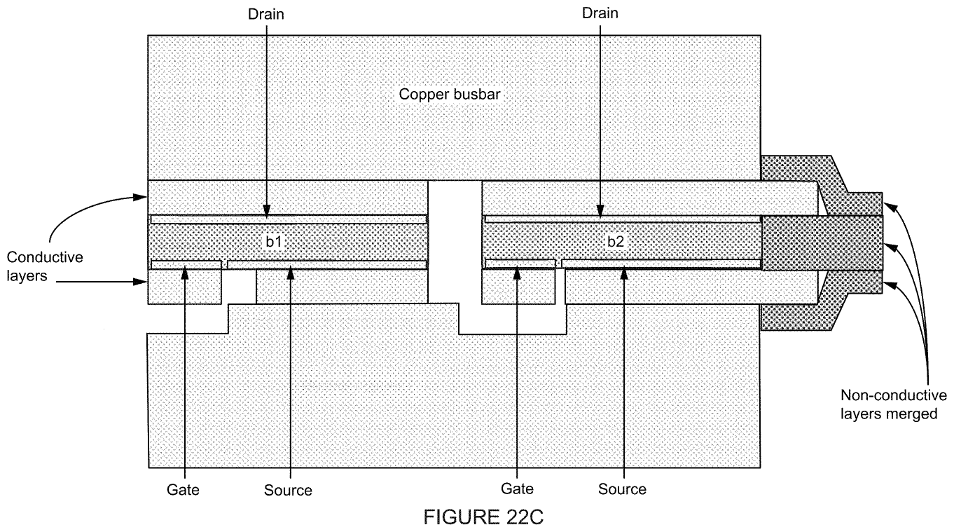

FIG. 22B shows a semiconductor switch configuration known as a back-to-back or reverse-blocking configuration. Switch transistor b2 is in the same orientation relative to switch transistor b1. In this configuration, switches are configured in a source b1 to source b2 connection. FIG. 22A shows the sources connected by connection to conductive layer 602, which is configured to span across the source terminals of any components configured in the back to back configuration. Drain terminals of the components b1, b2 are connected to separate conductive layers 601a and 602b. Gate terminals are also connected together. Other numbers of components are possible, for example, by configuration of further switch components in parallel with those already shown.

In some embodiments, a non-conductive layer 603 is located between the two conductive layers 601 and 602 in regions around the transistors. In some embodiments, the non-conductive layer leaves a gap between switch transistors.

In this embodiment, there are two additional non-conductive layers 604, 605 on the outside of the conductive layers. In other embodiments there may not be any outer non-conductive layers. The outer non-conductive layers 604, 605 can optionally be merged together with the middle non-conductive layer 603 adjacent to a switch transistor b2, as shown in FIG. 22A.

The merging of non-conductive layers offers a benefit of sealing components embedded between layers to keep moisture out. In this embodiment there are three non-conductive layers, in other embodiments only two non-conductive layers need to be merged to seal in a switch transistor for the same benefit/purpose.

When both switches are off, current is blocked in both directions. Note that FIG. 22A is a two dimensional sectional view, not showing that the gates are also connected as indicated by the circuit of FIG. 22B. A three dimensional version of FIG. 22A would be able to show such connections into/out of the page of FIG. 22A.

In operation, when both switches are on, currents can flow in both directions. Therefore when both switches are on, conductor 601a conducts currents to conductive layer 602, which in turn conducts to conductive layer 601b. In this circuit configuration, 601a can be considered as the input node, and 601b can be considered as the output node. Alternatively, 601a can be considered as the output node, and 601b can be considered as the input node.

FIG. 22C shows an alternative construction of the circuit of FIG. 22B, where conductive layers of a circuit region are layered with further conductive materials such as a busbar. In some embodiments, the busbar features recesses, cutouts or moldings which provide a region around the gates of switch transistors such that short circuits are avoided. Such regions may be sized appropriately to account for structural displacement of any layer, as may be caused by mechanical movement or thermal expansion of any one or more parts.

In some embodiments, electronic assembly comprises the upper and lower conductive layers 601, 602 where one conductive layer spans the source terminals of multiple components. At least one of the conductive layers also comprises terminal coupling regions, and therefore together defines a primary current path from one terminal coupling region, through the circuit region where the components are located, and to the next terminal coupling region. The electronic component(s) are disposed in the primary current path and operate to, for example, control current flow from one terminal coupling region to the next. In some embodiments, the components are configured to selectively bypass an energy storage unit and/or reversibly disconnect an energy storage unit. The components are configured to perform such operation by breaking and or redirecting the primary current path between any two terminal coupling regions. In other embodiments, the upper and lower conductive layer form a circuit region, and the depicted busbars form the terminal coupling region. Layered conductive materials may therefore comprise the terminal coupling region and circuit region, however only the circuit region is configured to support the electronic components in such instances.

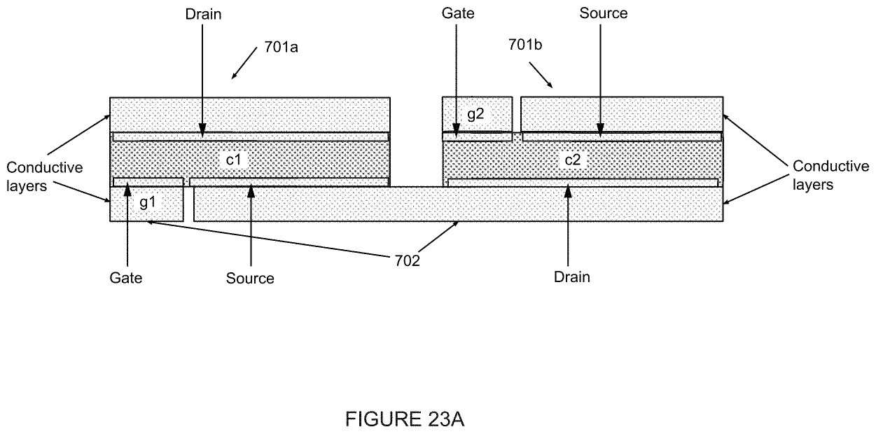

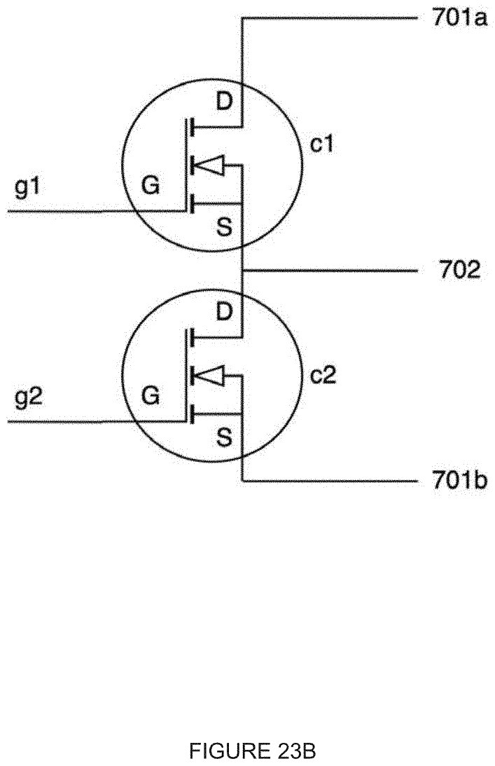

FIGS. 23A and 23B show a pair of exemplary and representative embedded switch components c1 and c2 which are configured with connected drain and source terminals. This circuit configuration, depicted in FIG. 23B, is also known as a half-bridge configuration, or an or -selection configuration. Switch transistor c2 is flipped in orientation relative to switch transistor c1, so that the source of transistor c1 is directly connected with the drain of transistor c2.

Two conductive layers 701 and 702 are shown. In particular the lower conductive layer is configured to span between the source and drain terminals of the pair of components. The upper conductive layer comprises at least two regions, one region configured to connect with the drain of the first switch, and a second region configured to connect with the source of the second switch.

In some embodiments, one or more additional conductive layers are disposed between the conductive layers and/or on the outside of the conductive layers. These are not shown, but can be understood to be in some embodiments as shown in earlier figures.

When switch c1 is on and switch c2 is off, conductor 701a conducts to conductor 702. When switch c1 is off and switch c2 is on, conductor 701b instead conducts to copper 702. In this circuit configuration, 701a and 701b can be considered as the input nodes, 702 can be considered as the output node. Alternatively, 702 can be considered the input node, and 701a and 701b can be considered the output nodes.

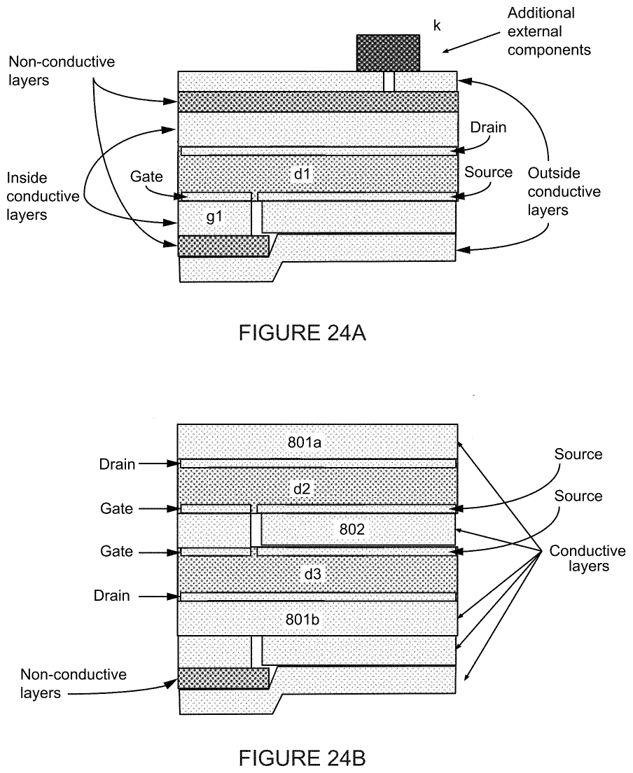

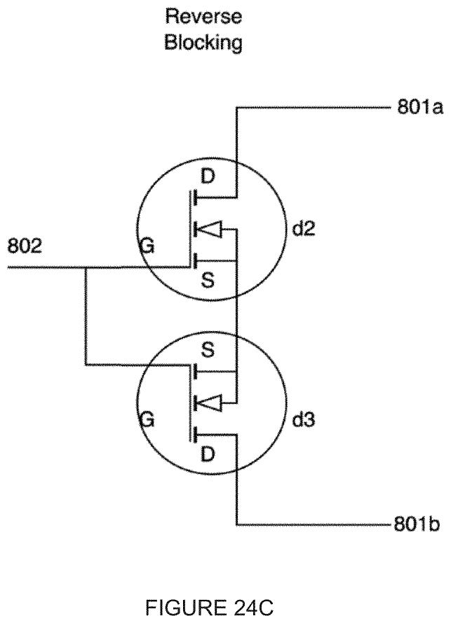

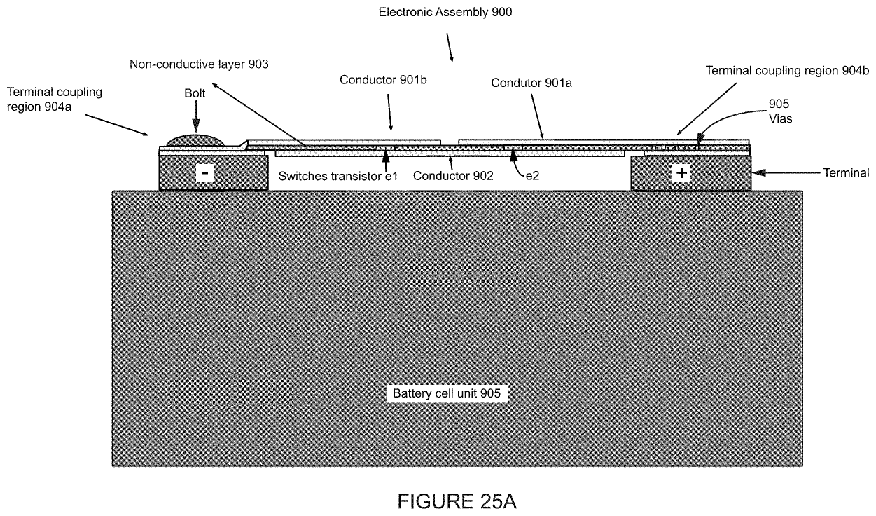

FIGS. 24A, 24B, and 24C show exemplary and representative embodiments where the electronic assembly further comprises additional vertically arranged layers. In exemplary FIG. 24A, the electronic assembly has additional layers which are arranged vertically about the circuit region and switching components arranged in a single plane. In FIG. 24B, the electronic assembly has stacked circuit regions and switching components are placed on each of the stacked circuit regions.

FIG. 24C shows a circuit diagram of switching components arranged in a reverse blocking circuit. The reverse blocking circuit may be particularly desirable due to the vertical orientation of the switch components and the alignment of terminals for connection.

In the exemplary embodiment of FIG. 24A, there are two outside conductive layers separated from the inside conductive layers by insulating non-conductive layers, there can be other external components (k) disposed on top of the outermost conductive layer, in addition to a switch transistor d1 embedded between conductive layers.

In the exemplary embodiment of FIG. 24B, the circuit regions share a common conductive layer 802 which is configured to interconnect the vertically arranged components d2 and d3.

In some embodiments, multiple switch transistors can be simultaneously used in different layers as shown in FIG. 24B. In this embodiment of FIG. 24B, switch transistor d2 is disposed between conductive layers 801a and 802, switch transistor d3 is disposed between conductive layers 802 and 801b.

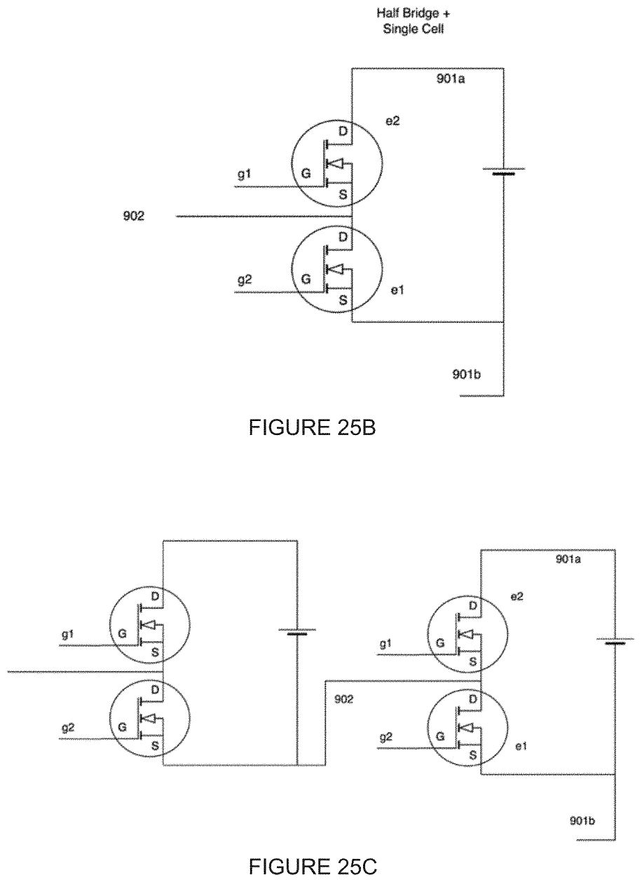

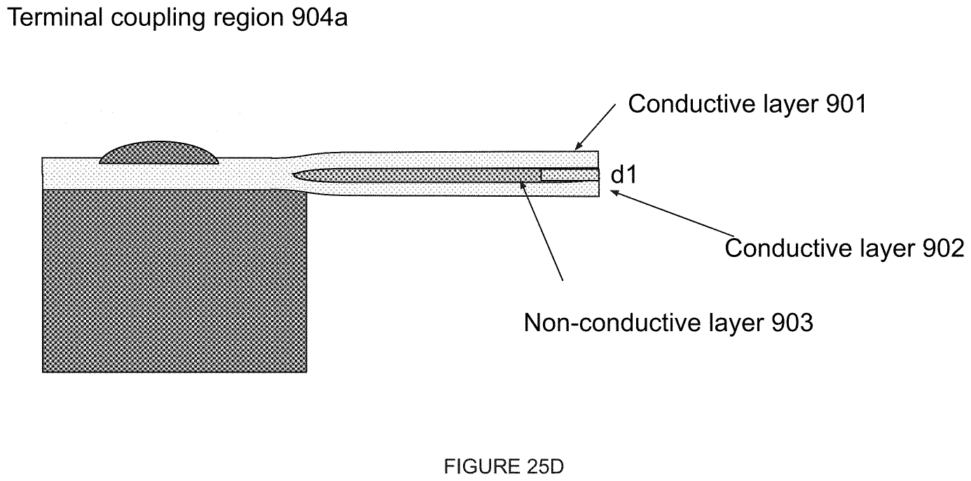

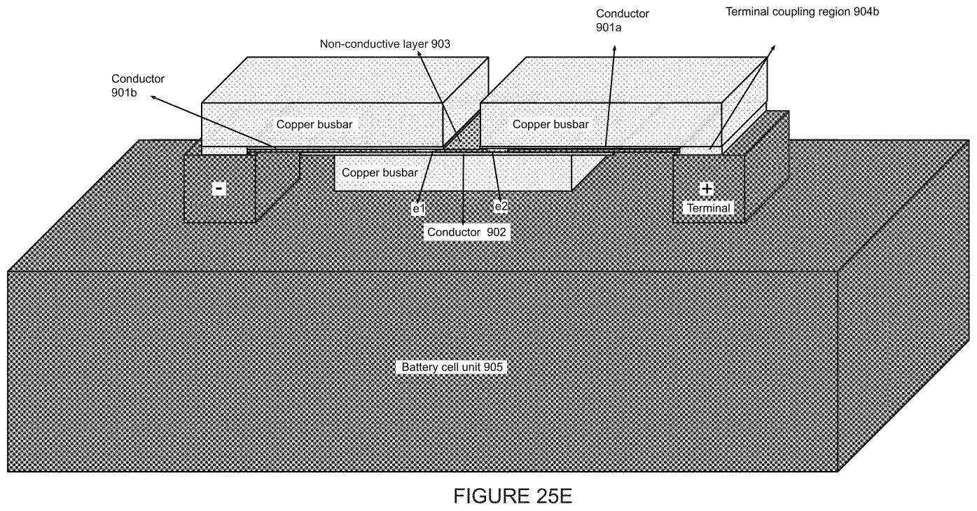

FIGS. 25A, 25B, 25C, 25D and 25E show an exemplary embodiment of an electronic assembly where a single electronics board is adapted to span between two terminals of a single cell. FIG. 25C shows an example implementation where another cell is connected. FIG. 25A shows a side sectional view of the electronic assembly mounted on an energy storage cell unit. FIG. 25E shows an isometric view of the electronic assembly 900 with additional busbars added to reinforce conductive layers 901 and 902. FIG. 25B shows the circuit diagram of the transistor switches e1 and e2 in a half-bridge configuration. FIG. 25D shows a detailed view of the terminal coupling region 904a, where two conductive layers are merged together so that vias are not required.

FIG. 25A also shows two exemplary ways of connecting two conductive layers. At the terminal coupling region 904b of the positive terminal, vias 905 are used to connect two conductive layers. On the coupling region 904 of the negative terminal, conductive layers are contoured so as to be merged and thus electrically connected together, and by virtue, no vias are needed to interconnect the conductive layers. FIG. 25D shows a detailed view of an embodiment of the terminal coupling region 904a, where two conductive layers are merged together so that vias are not required to join conductive layers on opposing board surfaces and noting where a gap in the lower conductive layer is not visible as it is in FIG. 25A and FIG. 25E. The merged region of the conductive layers which form the terminal coupling region 904a may be bolted to a terminal as shown in this embodiment. In other embodiments other suitable methods including but not limited to welding, soldering, fusing or compression fit may be used.

In a preferred embodiment, vias are not required to connect two conductive layers, and instead the nonconductive layer is removed and at least one conductive layer is contoured to merge with another conductive layer to make the electrical connection. This has benefits including better electrical and thermal conductivity between conductive layers due to there being a shorter distance and large area of contact between the conductive layers leading to a lower resistance. It also allows for alternative bonding methods to busbars or terminals. In other embodiments, vias 905 may be used instead.

The contouring of conductive layers as explained above may occur at a terminal coupling region, at the location of the component placement on the circuit region, or anywhere else in the circuit regions of the electronic assembly. Its location does not affect its function, purpose or the benefits offered.

In some embodiments there are one or more additional non-conductive layers on the outside of the electronic assembly (with or without copper busbars). This has a benefit of enhancing safety during handling by providing insulation of the electronic assembly.

In the exemplary embodiment of FIG. 25, an electronic assembly 900 is connected to both terminals of an energy storage cell at the terminal coupling regions 904. The electronic assembly 900 has an upper conductive layer 901 and a lower conductive layer 902, and a non-conductive layer 903 in between them. Switch transistors e1 and e2 are disposed between the two conductive layers. In this half-bridge configuration, switch transistor e1 and switch transistor e2 are in opposite orientations (flipped relative to the other), and the drain of e1 is connected directly with the source of e2 via the lower conductive layer 902. Only one of the switches would be turned on at any time.

This configuration of the switches was shown also FIG. 23. In this embodiment of FIG. 25, an energy storage cell is connected at both terminals to the electronic assembly.

FIG. 25 therefore shows one or more electronics boards comprising terminal coupling regions arranged in a predetermined geometrical alignment and adapted for connection to terminals of at least one energy storage unit, at least one circuit region comprising at least a first conductive layer and a second non-conductive layer, and electronic components disposed on and connected to the conductive layer of the circuit region. The terminal coupling regions are formed from two conductive layers which may be merged together, or connected through vias/other conductive means, in at least a region where a terminal is to connect. As explained above the merging may be at any location in the circuit region and/or terminal coupling regions. In other regions, the conductive layers are separated by a nonconductive layer of the assembly. The terminal coupling regions and the at least one circuit region define a primary path of electrical current between terminal coupling regions of the same or separate energy storage units. In particular in FIG. 25A and FIG. 25D, when the corresponding battery energy storage unit is connected in series with another battery energy storage unit (such as shown in the exemplary embodiment of FIG. 25C), the primary path of current originates at a terminal coupling region connected to a terminal of a first cell, travels through circuit regions/terminal coupling regions, and terminates at a terminal coupling region connected to a terminal of an adjacent cell (see the exemplary embodiment of FIG. 25C).

The electronic assembly either disconnects the negative terminal or the positive terminal of the cell unit depending on the states of the switch transistors. If conductor 901b is defined as an input node, and conductor 902 is the output node, the electronic assembly either connects the input node 901b (negative of the cell) to 902 via the cell and e2 to output node 901b by turning e1 off and e2 on. Or directly to 902 via e1 bypassing the cell, by turning e1 on and e2 off. The two possible states of operation are shown in Table 1, below. It should also be noted that conductor 901a could be the input node instead.

TABLE 1

| Switches | Terminals |
|---|---|
| e1 Off e2 On | Negative terminal is disconnected from the |
| | Output node 902 (lower conductive layer) |
| | Positive terminal is connected to the |
| | output node 902 (lower conductive layer) |
| | Includes the cell |
| e1 On e2 Off | Negative terminal is connected to output |
| | node 902 (lower conductive layer) |
| | Positive terminal is disconnected from the |
| | output node 902 (lower conductive layer) |
| | Bypasses the cell |

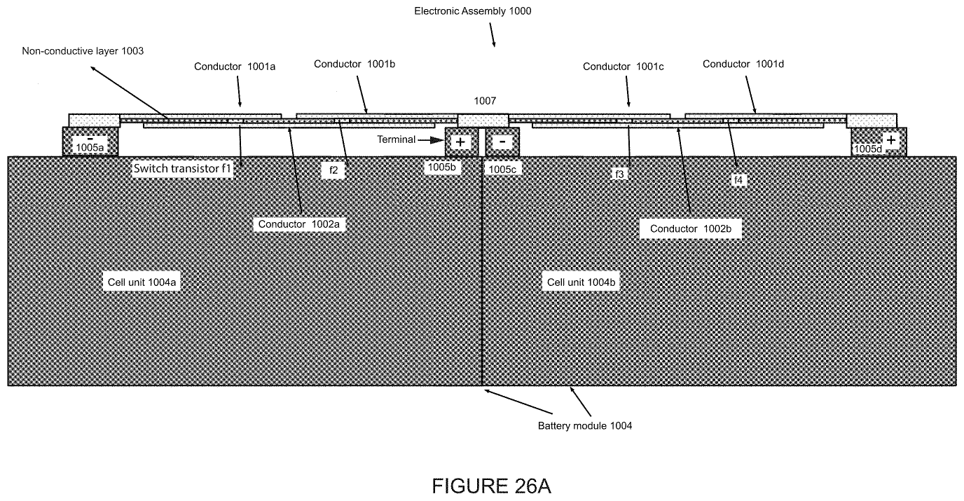

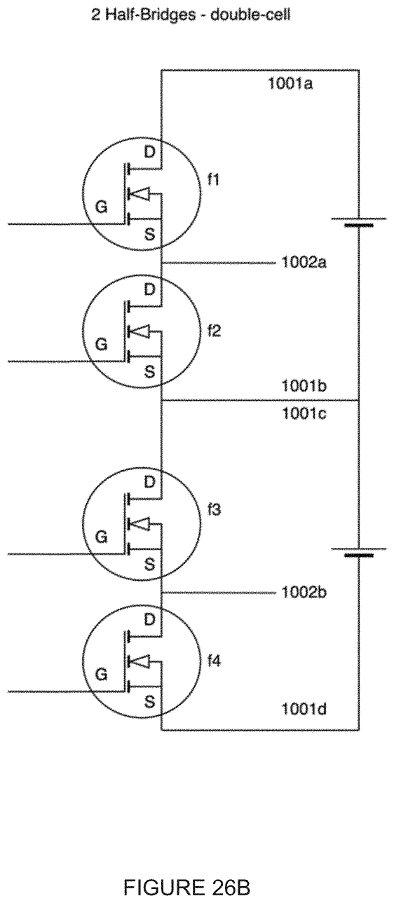

FIGS. 26A and 26B show an exemplary embodiment of an electronic assembly where a single electronics board 1000 is adapted to span between four cell terminals of two adjacent energy storage cells 1004a and 1004b, the two cell units form a single energy storage module 1004, and where a positive terminal 1005b of a first cell unit 1004a within a first module 1004 and the negative terminal 1005c of a second series-connected cell unit of the same module 1004 are connected together to the electronic assembly 1000 at one contact point 1007. Switching components are arranged in the primary path of electrical current and configured in two half bridges, FIG. 26B shows the circuit diagram of this embodiment.

In this two half-bridge configuration (or-selection configuration), switch transistors f1 and f2 are in opposite orientations, and the drain of f1 is connected directly with the source of f2 via the lower conductive layer 1002a. This configuration was also shown in the exemplary embodiment in FIG. 23. Only one of the switches would be turned on at any one time to prevent shorting of the cells. Likewise for switch transistors f3 and f4, also in a half-bridge configuration. This two half-bridge configuration could be used to implement at least a part of the circuit layout shown in FIG. 4—the two cell units being 104a 104b.

In some embodiments, busbars or any other conductive materials may be added to the shown conductive layers to serve the purposes of improving current carrying capacity and/or improving thermal dissipation and/or improving structural support. In some embodiments non-conductive materials may be added to improve structural support.

In some embodiments there can be one or more additional non-conductive layers on the outside of the electronic assembly (with or without copper busbars). This has a benefit of enhancing safety during handling by providing insulation of the electronic assembly.

FIG. 26A therefore shows one or more electronics boards comprising terminal coupling regions arranged in a predetermined geometrical alignment and adapted for connection to terminals of energy storage units, at least one circuit region comprising at least a first conductive layer and a second non-conductive layer, and electronic components disposed on and connected to the conductive layer of the circuit region. The terminal coupling regions are formed from two conductive layers which may be merged together, or connected through vias/other conductive means, in at least a region where a terminal is to connect. As explained earlier the merging may be at any location in the circuit region and/or terminal coupling regions. In other regions, the conductive layers are separated by a nonconductive layer of the assembly. The terminal coupling regions and the at least one circuit region define a primary path of electrical current between energy storage units.

In the electronic assembly shown, there are electronics boards comprising terminal coupling regions arranged in a predetermined geometrical alignment and adapted for connection to terminals of energy storage units, the at least one circuit region comprises at least an upper and lower conductive layer, and a non-conductive layer arranged between the conductive layers. The nonconductive layer acts to separate regions of the conductive layers and to physically separate the layers such that there is space between the layers for electronic components to be located. The components and nonconductive layers may together act to separate the conductive layers. Terminals of the electronic components may be connected to the upper and lower conductive layers such that the components can be operated to connect the layers when configured as such.

Referring to FIG. 26B, the two cell units can be selectively bypassed/connected in various combinations to achieve a desired outcome. Either cell could be bypassed, both could be bypassed, or both could be connected. The input terminal of the system is the lower conductive layer 1002a, and the output terminal of the system is the lower conductive layer 1002b. For example, to connect both cell units, switch transistors f1 and f4 are on and f2 f3 are off, and a current is conducted from the input terminal 1002a, via the turned-on switch transistor f1 to the negative terminal on the left 1005a, down and rightward through the cell unit 1004a, to the junction contact point 1007, at which point it continues to travel through cell unit 1004b up to the positive terminal (1005d) of cell unit 1004b, to the conductive layer 1001d, via the turned on switch transistor f4 (while f3 is off), and finally to the lower conductive layer 1002b, which is also the output terminal.

Table 2, below, shows four possible states of operation:

TABLE 2

| Switches | Cells |
|---|---|
| f1 ON, f2 OFF, f3 OFF, f4 ON | Both cell units are connected |
| f1 OFF, f2 ON, f3 OFF, f4 ON | Left cell unit is bypassed, |
| | Right cell unit is connected |
| f1 ON, f2 OFF, f3 ON, f4 OFF | Left cell unit is connected, |
| | right cell unit is bypassed |
| f1 Off, f2 ON, f3 ON, f4 OFF | Both cell units are bypassed |

From the foregoing, it will be appreciated that, although specific embodiments have been described herein for purposes of illustration, various modifications may be made without deviating from the spirit and scope of the invention. Accordingly, the invention is not limited except as by the appended claims and the elements recited therein. In addition, while certain aspects of the invention are presented below in certain claim forms, the inventors contemplate the various aspects of the invention in any available claim form.

What is claimed is:

1. An electronic assembly comprising:
one or more electronics boards comprising:
terminal coupling regions arranged in a predetermined geometrical alignment and adapted for connection to terminals of energy storage units,
at least one circuit region comprising at least a first conductive layer and a second non-conductive layer,
two or more electronic components disposed on and connected to the conductive layer of the at least one circuit region;
wherein the terminal coupling regions and the at least one circuit region define a primary path of electrical current between a plurality of energy storage units;
wherein at least one of the electronic components is disposed in the primary current path; and
wherein at least one part of the terminal coupling regions and/or at least one part of the at least one circuit region is characterized by a mechanical bending characteristic configured to permit at least some displacement from the predetermined geometrical alignment and/or a combined thickness characteristic.

2. The electronic assembly of claim 1, wherein the terminal coupling regions of the electronics boards comprise at least three terminal coupling regions adapted to span between cell terminals of at least three energy storage units in the geometrical alignment.

3. The electronic assembly of claim 1, wherein:
the primary current path comprises a series connection between at least two terminal coupling regions, and
the at least one of the two or more electronic components comprises a switch component, or a DC/DC converter component, and is configured to selectively bypass and reversibly disconnect any one or more storage units from the series connection.

4. The electronic assembly of claim 1, wherein at least one of the terminal coupling regions is electrically coupled to one or more junctions between two serially connected energy storage units.

5. The electronic assembly of claim 1, wherein at least one of the plurality of energy storage units comprises a charge capacity of at least 20 ampere hours.

6. The electronic assembly of claim 1, wherein at least one of the electronic components comprises an electronics circuit board with mounted discrete components or an integrated electronic circuit element.

7. The electronic assembly of claim 1, wherein at least one of the terminal coupling regions and/or at least one of the circuit regions further comprises layers of a resiliently deformable material.

8. The electronic assembly of claim 1, wherein at least one of the terminal coupling regions and/or at least one of the circuit regions further comprises at least two conductive layers separated by at least one non-conductive layer, and one or more vias extending between the at least two conductive layers.

9. The electronic assembly of claim 1, wherein at least one of the circuit regions further comprises a layer substantially continuous with at least one of the terminal coupling regions.

10. The electronic assembly of claim 1, wherein at least one of the at least one circuit region and/or the terminal coupling regions further comprise one or more support layers.

11. The electronic assembly of claim 10, wherein the one or more support layers are substantially continuous with at least one of the circuit regions and/or one of the terminal coupling regions of the electronics board.

12. The electronic assembly of claim 1, wherein one or more coupling region of the terminal coupling regions is configured for coupling to the terminal of a storage unit by a fastener, fusing, or welding.

13. The electronic assembly of claim 10, wherein one or more terminal coupling region of the terminal coupling regions further comprises a temperature sensor configured to measure a temperature of the electronic assembly proximate to the terminal.

14. The electronic assembly of claim 13, wherein one or more terminal coupling region of the terminal coupling regions further comprises a voltage sensor configured to measure a voltage at the terminal.

15. The electronic assembly of claim 14, wherein:
one or more terminal coupling region of the terminal coupling regions further comprises a plurality of conductive segments,
at least one conductive segment of the plurality of conductive segments is configured to couple to the temperature sensor and/or the voltage sensor, and
the primary current path comprises one or more other segments.

16. The electronic assembly of claim 15, wherein the one or more support layers comprise one or more slits, ridges, apertures, and/or recesses disposed between at least some of the plurality of conductive segments of the terminal coupling region.

17. The electronic assembly of claim 10, wherein the one or more support layers comprise one or more slits, ridges, apertures and/or recesses arranged to border, at least in part, the terminal coupling region.

18. The electronic assembly of claim 1, wherein:
the terminal region comprises a conductive pad segmented by a plurality of non-conductive regions, and
at least some of the plurality of non-conductive regions comprises one or more slits, ridges, apertures, and/or recesses.

19. The electronic assembly of claim 2, wherein the primary current path further comprises one or more fuseable circuits arranged to couple at least one terminal coupling region of the terminal coupling regions to the at least one circuit region and/or at least one other terminal coupling region of the terminal coupling regions.

20. The electronic assembly of claim 19, wherein the one or more fuseable circuits comprise a printed conductive track having a geometrical constraint nominally configured for destruction above about 1000 amps.

21. The electronic assembly of claim 1, wherein the electronics board comprises one or more of: polyimide, KAPTON®, polyethylene terephthalate, or polyethylene naphthalate.

22. The electronic assembly of claim 1, wherein the electronics assembly further comprises one or more captive fastener structure that maintain a bolt in position when not in a fastened state in relation to the electronics assembly and/or one or more energy storage units.

23. The electronic assembly of claim 1, wherein the bending characteristic is defined as one or more of:
the electronic assembly having at room temperature a flexural modulus of less than 12 GPa;
the electronic assembly having at room temperature a flexural modulus of around 6 GPa;
a material in one or more non-conductive layers having at room temperature a flexural modulus of less than 10 GPa;
a material in one or more non-conductive layers having at room temperature a flexural modulus of around 3 GPa;
the electronic assembly having at room temperature a flexural strength of less than 300 MPa;
the electronic assembly having at room temperature a flexural strength of around 150 MPa;
a material in one or more non-conductive layers having at room temperature a flexural strength of less than 300 MPa; or
a material in one or more non-conductive layers having at room temperature a flexural strength of less than 150 MPa.

24. The electronic assembly of claim 1, wherein the combined thickness characteristic is defined as one or more of:
one or more support layers having a thickness of around 1 mm;
one or more support layers of more than 0.4 mm;
one or more thin non-conductive layers and one or more conductive layers having a combined thickness of up to 0.4 mm;
one or more thin non-conductive layers and one or more conductive layers having a combined thickness of up to 0.2 mm;
one or more thin non-conductive layers and one or more conductive layers having a combined thickness of around 0.1 mm;
a first non-conductive layer having a thickness of up to 0.08 mm; or
a first non-conductive layer having a thickness of up to 0.02 mm.
